(19) United States
(12) Patent Application Publication
(10) Pub. No.: US 2026/0080914 A1
(43) Pub. Date: Mar. 19, 2026

(54) SEMICONDUCTOR MEMORY DEVICE

(71) Applicant: Kioxia Corporation, Tokyo (JP)

(72) Inventors: Mutsumi OKAJIMA, Yokkaichi Mie (JP); Ryota NARASAKI, Ibaraki Osaka (JP); Takamitsu OCHI, Nagoya Aichi (JP)

(73) Assignee: Kioxia Corporation, Tokyo (JP)

(21) Appl. No.: 19/074,186

(22) Filed: Mar. 7, 2025

(30) Foreign Application Priority Data
Sep. 17, 2024 (JP) 2024-160477

(51) Int. Cl. G11C 5/06; H01L 23/00; H01L 25/065; H10B 41/10; H10B 41/27; H10B 43/10; H10B 43/27; H10B 80/00

(52) U.S. Cl. CPC G11C 5/063; H10B 41/10; H10B 41/27; H10B 43/10; H10B 43/27; H10B 80/00; H10W 90/00; H10W 90/297; H10W 90/794

(57) ABSTRACT

A semiconductor memory device comprises: memory layers; a via wiring; a first wiring provided on one side with respect to memory layers; and an insulating layer provided on the other side with respect to memory layers, and covering an end portion of the via wiring. Memory layers each comprise: a semiconductor layer connected to the via wiring; a gate electrode facing the semiconductor layer; a second wiring connected to the gate electrode; and a memory portion connected to the semiconductor layer. The via wiring comprises: a conductive member; and an inner region having its outer peripheral surface surrounded by the conductive member. An end portion on an insulating layer side of the inner region is not covered by the conductive member, but is covered by the insulating layer, or is continuous with the insulating layer.

### CROSS-REFERENCE TO RELATED APPLICATIONS

This application is based upon and claims the benefit of Japanese Patent Application No. 2024-160477, filed on Sep. 17, 2024, the entire contents of which are incorporated herein by reference.

### BACKGROUND

### Field

The present embodiments relate to semiconductor memory devices.

### Description of the Related Art

As degree-of-integration of semiconductor memory devices continues to rise, study is underway into how three-dimensionality of the semiconductor memory devices may be further promoted.

### BRIEF DESCRIPTION OF THE DRAWINGS

FIG. 1 is a schematic exploded perspective view showing a configuration example of a semiconductor memory device according to a first embodiment;

FIG. 2 is a schematic circuit diagram showing configurations of same semiconductor memory device;

FIG. 3 is a schematic cross-sectional view showing a part of a configuration of same semiconductor memory device;

FIG. 4 is a schematic perspective view showing a part of a configuration of same semiconductor memory device;

FIG. 5 is a schematic cross-sectional view showing a part of a configuration of a memory layer ML;

FIG. 6 is a schematic cross-sectional view showing a part of a configuration of the memory layer ML;

FIG. 7 is a cross-sectional view of the structure shown in FIG. 6 taken along the line A1-A1′ and viewed along a direction of the arrows;

FIG. 8 is a schematic cross-sectional view showing a part of a configuration of a transistor layer TL;

FIG. 9 is a cross-sectional view of the structure shown in FIG. 8 taken along the line B1-B1′ and viewed along a direction of the arrows;

FIG. 10 is a schematic cross-sectional view showing a part of a configuration of a bit line BL;

FIG. 11 is a cross-sectional view of the structure shown in FIG. 10 taken along the line C1-C1′ and viewed along a direction of the arrows;

FIG. 12 is a schematic cross-sectional view for explaining a method of manufacturing same semiconductor memory device;

FIG. 13 is a schematic cross-sectional view for explaining same method of manufacturing;

FIG. 14 is a schematic cross-sectional view for explaining same method of manufacturing;

FIG. 15 is a schematic cross-sectional view for explaining same method of manufacturing;

FIG. 16 is a schematic cross-sectional view for explaining same method of manufacturing;

FIG. 17 is a schematic cross-sectional view for explaining same method of manufacturing;

FIG. 18 is a schematic cross-sectional view for explaining same method of manufacturing;

FIG. 19 is a schematic cross-sectional view for explaining same method of manufacturing;

FIG. 20 is a schematic cross-sectional view for explaining same method of manufacturing;

FIG. 21 is a schematic cross-sectional view for explaining same method of manufacturing;

FIG. 22 is a schematic cross-sectional view for explaining same method of manufacturing;

FIG. 23 is a schematic cross-sectional view for explaining same method of manufacturing;

FIG. 24 is a schematic cross-sectional view for explaining same method of manufacturing;

FIG. 25 is a schematic cross-sectional view for explaining same method of manufacturing;

FIG. 26 is a schematic cross-sectional view for explaining same method of manufacturing;

FIG. 27 is a schematic cross-sectional view for explaining same method of manufacturing;

FIG. 28 is a schematic cross-sectional view for explaining same method of manufacturing;

FIG. 29 is a schematic cross-sectional view for explaining same method of manufacturing;

FIG. 30 is a schematic cross-sectional view for explaining same method of manufacturing;

FIG. 31 is a schematic cross-sectional view for explaining same method of manufacturing;

FIG. 32 is a schematic cross-sectional view for explaining same method of manufacturing;

FIG. 33 is a schematic cross-sectional view for explaining same method of manufacturing;

FIG. 34 is a schematic cross-sectional view for explaining same method of manufacturing;

FIG. 35 is a schematic cross-sectional view for explaining same method of manufacturing;

FIG. 36 is a schematic cross-sectional view for explaining same method of manufacturing;

FIG. 37 is a schematic cross-sectional view for explaining same method of manufacturing;

FIG. 38 is a schematic cross-sectional view for explaining same method of manufacturing;

FIG. 39 is a schematic cross-sectional view for explaining same method of manufacturing;

FIG. 40 is a schematic cross-sectional view for explaining same method of manufacturing;

FIG. 41 is a schematic cross-sectional view for explaining same method of manufacturing;

FIG. 42 is a schematic cross-sectional view for explaining same method of manufacturing;

FIG. 43 is a schematic cross-sectional view for explaining same method of manufacturing;

FIG. 44 is a schematic cross-sectional view for explaining same method of manufacturing;

FIG. 45 is a schematic cross-sectional view for explaining same method of manufacturing;

FIG. 46 is a schematic cross-sectional view for explaining same method of manufacturing;

FIG. 47 is a schematic cross-sectional view for explaining same method of manufacturing;

FIG. 48 is a schematic cross-sectional view for explaining same method of manufacturing;

FIG. 49 is a schematic cross-sectional view for explaining same method of manufacturing;

FIG. 50 is a schematic cross-sectional view for explaining same method of manufacturing;

FIG. 51 is a schematic cross-sectional view for explaining same method of manufacturing;

FIG. 52 is a schematic cross-sectional view for explaining same method of manufacturing;

FIG. 53 is a schematic cross-sectional view for explaining same method of manufacturing;

FIG. 54 is a schematic cross-sectional view for explaining same method of manufacturing;

FIG. 55 is a schematic cross-sectional view for explaining same method of manufacturing;

FIG. 56 is a schematic cross-sectional view for explaining same method of manufacturing;

FIG. 57 is a schematic cross-sectional view for explaining same method of manufacturing;

FIG. 58 is a schematic cross-sectional view for explaining same method of manufacturing;

FIG. 59 is a schematic cross-sectional view showing a part of a configuration of a semiconductor memory device according to modified example 1 of the first embodiment;

FIG. 60 is a cross-sectional view of the structure shown in FIG. 59 taken along the line D1-D1′ and viewed along a direction of the arrows;

FIG. 61 is a schematic cross-sectional view showing a part of a configuration of a semiconductor memory device according to modified example 2 of the first embodiment;

FIG. 62 is a schematic circuit diagram showing configurations of a semiconductor memory device according to a second embodiment;

FIG. 63 is a schematic cross-sectional view showing a part of a configuration of same semiconductor memory device;

FIG. 64 is a schematic cross-sectional view showing a part of a configuration of same semiconductor memory device;

FIG. 65 is a schematic cross-sectional view for explaining a method of manufacturing same semiconductor memory device;

FIG. 66 is a schematic cross-sectional view for explaining same method of manufacturing;

FIG. 67 is a schematic cross-sectional view for explaining same method of manufacturing;

FIG. 68 is a schematic cross-sectional view for explaining same method of manufacturing;

FIG. 69 is a schematic cross-sectional view for explaining same method of manufacturing;

FIG. 70 is a schematic cross-sectional view for explaining same method of manufacturing;

FIG. 71 is a schematic cross-sectional view for explaining same method of manufacturing;

FIG. 72 is a schematic cross-sectional view for explaining same method of manufacturing;

FIG. 73 is a schematic cross-sectional view for explaining same method of manufacturing;

FIG. 74 is a schematic cross-sectional view for explaining same method of manufacturing;

FIG. 75 is a schematic cross-sectional view for explaining same method of manufacturing;

FIG. 76 is a schematic cross-sectional view for explaining same method of manufacturing;

FIG. 77 is a schematic cross-sectional view for explaining same method of manufacturing;

FIG. 78 is a schematic cross-sectional view for explaining same method of manufacturing;

FIG. 79 is a schematic cross-sectional view for explaining same method of manufacturing;

FIG. 80 is a schematic cross-sectional view for explaining same method of manufacturing;

FIG. 81A is a schematic cross-sectional view showing a part of a configuration of a semiconductor memory device according to a modified example of the second embodiment;

FIG. 81B is a schematic cross-sectional view for explaining a method of manufacturing same semiconductor memory device;

FIG. 82 is a schematic cross-sectional view showing a part of a configuration of a semiconductor memory device according to a third embodiment;

FIG. 83 is a schematic cross-sectional view showing a part of a configuration of same semiconductor memory device;

FIG. 84 is a cross-sectional view of the structure shown in FIG. 83 taken along the line A3-A3′ and viewed along a direction of the arrows;

FIG. 85 is a schematic cross-sectional view for explaining a method of manufacturing same semiconductor memory device;

FIG. 86 is a schematic cross-sectional view for explaining same method of manufacturing;

FIG. 87 is a schematic cross-sectional view for explaining same method of manufacturing;

FIG. 88 is a schematic cross-sectional view for explaining same method of manufacturing;

FIG. 89 is a schematic cross-sectional view for explaining same method of manufacturing;

FIG. 90 is a schematic cross-sectional view for explaining same method of manufacturing;

FIG. 91 is a schematic cross-sectional view for explaining same method of manufacturing;

FIG. 92 is a schematic cross-sectional view for explaining same method of manufacturing;

FIG. 93 is a schematic cross-sectional view for explaining same method of manufacturing;

FIG. 94 is a schematic cross-sectional view for explaining same method of manufacturing;

FIG. 95 is a schematic cross-sectional view for explaining same method of manufacturing;

FIG. 96 is a schematic cross-sectional view for explaining same method of manufacturing;

FIG. 97 is a schematic cross-sectional view for explaining same method of manufacturing;

FIG. 98 is a schematic cross-sectional view for explaining same method of manufacturing;

FIG. 99 is a schematic cross-sectional view for explaining same method of manufacturing;

FIG. 100 is a schematic cross-sectional view for explaining same method of manufacturing;

FIG. 101 is a schematic cross-sectional view for explaining same method of manufacturing;

FIG. 102 is a schematic cross-sectional view for explaining same method of manufacturing;

FIG. 103 is a schematic cross-sectional view for explaining same method of manufacturing; and

FIG. 104 is a schematic cross-sectional view for explaining same method of manufacturing.

### DETAILED DESCRIPTION

A semiconductor memory device according to one embodiment comprises: a plurality of memory layers arranged in a first direction; a via wiring extending in the first direction; a first wiring which is provided on one side in the first direction with respect to the plurality of memory layers, and extends in a second direction intersecting the first direction; and an insulating layer which is provided on the other side in the first direction with respect to the plurality of memory layers, and covers an end portion of the via wiring. The plurality of memory layers each comprise: a semiconductor layer electrically connected to the via wiring; a gate electrode facing the semiconductor layer; a second wiring which extends in a third direction intersecting the first direction and the second direction, and is electrically connected to the gate electrode; and a memory portion which is provided on an opposite side to the second wiring in the second direction with respect to the semiconductor layer, and is electrically connected to the semiconductor layer. The via wiring comprises: a conductive member extending in the first direction; and an inner region extending in the first direction and having its outer peripheral surface surrounded by the conductive member. An end portion on an insulating layer side in the first direction of the inner region is not covered by the conductive member, and is covered by the insulating layer, or is continuous with the insulating layer.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of a configuration, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, when a first configuration is said to be “electrically connected between” a second configuration and a third configuration, it will sometimes mean that the first configuration, the second configuration, and the third configuration are connected in series, and the second configuration is electrically connected to the third configuration via the first configuration.

Moreover, in the present specification, when a circuit, or the like, is said to “make electrically continuous” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction intersecting a surface of the substrate will sometimes be referred to as a first direction. Moreover, a direction lying along a certain plane intersecting the first direction will sometimes be referred to as a second direction, and a direction intersecting the second direction along this plane will sometimes be referred to as a third direction. The first direction may coincide with the Z-direction, but need not do so. Moreover, the second direction and the third direction may correspond to any of the X-direction and the Y-direction, but need not do so.

Moreover, in the present specification, when a “center position” of a certain configuration is referred to, it may mean a position of the center of a circumscribed circle of this configuration, or may mean the center of gravity on an image of this configuration, for example.

### First Embodiment

### Structure of Memory Die MD

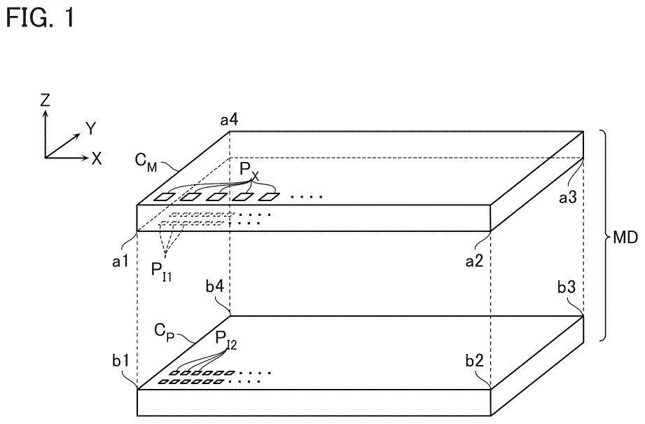

FIG. 1 is a schematic exploded perspective view showing a configuration example of a semiconductor memory device according to a first embodiment. As shown in FIG. 1, a memory die MD comprises a chip C_{M} and a chip C_{P}. The chip C_{M} comprises a memory cell array MCA. The chip C_{P} comprises a peripheral circuit, and so on, connected to the memory cell array MCA.

One surface of the chip C_{M} is provided with a plurality of external pad electrodes P_{X}. Moreover, the other surface of the chip C_{M} is provided with a plurality of first bonding electrodes P_{I1}. Moreover, one surface of the chip C_{P} is provided with a plurality of second bonding electrodes P_{I2}. Hereafter, the surface provided with the plurality of first bonding electrodes P_{I1}, of the chip C_{M} will be referred to as a front surface of the chip C_{M}, and the surface provided with the plurality of external pad electrodes P_{X}, of the chip C_{M} will be referred to as a back surface of the chip C_{M}. Moreover, the surface provided with the plurality of second bonding electrodes P_{I2}, of the chip C_{P} will be referred to as a front surface of the chip C_{P}, and a surface on an opposite side to the front surface, of the chip C_{P} will be referred to as a back surface of the chip C_{P}.

The chip C_{M} and the chip C_{P} are disposed so that the front surface of the chip C_{M} and the front surface of the chip C_{P} face each other. The respective plurality of first bonding electrodes P_{I1} are provided correspondingly to the plurality of second bonding electrodes P_{I2}, and are disposed at positions enabling them to be bonded to the plurality of second bonding electrodes P_{I2}. The first bonding electrodes P_{I1} and the second bonding electrodes P_{I2} function as bonding electrodes for bonding and making electrically continuous the chip C_{M} and chip C_{P}.

Note that in the example of FIG. 1, corners a1, a2, a3, a4 of the chip C_{M} respectively correspond to corners b1, b2, b3, b4 of the chip C_{P}.

### Circuit Configuration

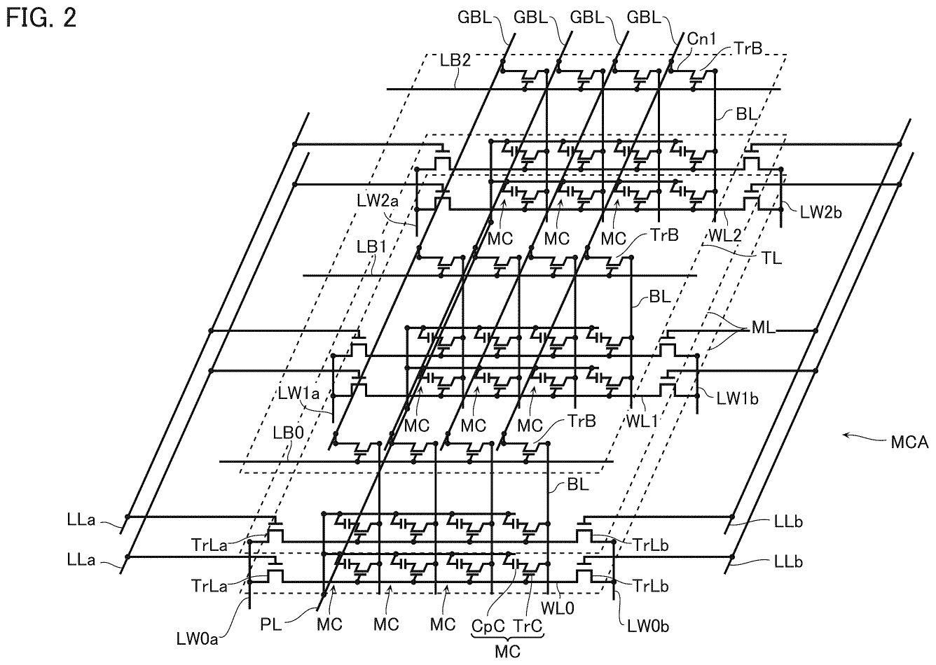

FIG. 2 is a schematic circuit diagram showing configurations of the semiconductor memory device according to the first embodiment. The memory cell array MCA comprises: a plurality of memory layers ML; a transistor layer TL; a plurality of bit lines BL connected to these plurality of memory layers ML and the transistor layer TL; a plurality of global bit lines GBL electrically connected to the plurality of bit lines BL via the transistor layer TL; and a plate line PL connected to the plurality of memory layers ML.

The memory layers ML each comprise: a plurality of word lines WL0-WL2 (hereafter, sometimes referred to as “word lines WL”); and pluralities of memory cells MC connected to these plurality of word lines WL0-WL2. The memory cells MC each comprise a transistor TrC and a capacitor CpC. One electrode of the transistor TrC is connected to the bit line BL. The other electrode of the transistor TrC is connected to the capacitor CpC. Note that the one and other electrodes of the transistor TrC function as a source electrode or a drain electrode, according to a voltage applied to the transistor TrC. A gate electrode of the transistor TrC is connected to any of the word lines WL0-WL2. One electrode of the capacitor CpC is connected to the other electrode of the transistor TrC. The other electrode of the capacitor CpC is connected to the plate line PL.

Note that each bit line BL is connected to a plurality of the memory cells MC corresponding to the plurality of memory layers ML.

In addition, the memory layers ML each comprise pluralities of transistors TrLa, TrLb (hereafter, sometimes referred to as “transistors TrL”) provided correspondingly to the plurality of word lines WL0-WL2. One electrode of each of the transistors TrL is connected to any of the word lines WL0-WL2. The other electrodes of the transistors TrL are respectively connected to word line select lines LW0a, LW0b, LW1a, LW1b, LW2a, LW2b (hereafter, sometimes referred to as “word line select lines LW”). Note that the one and other electrodes of the transistor TrL function as a source electrode or a drain electrode, according to a voltage applied to the transistor TrL. Respective gate electrodes of the transistors TrL are connected to layer select lines LLa, LLb (hereafter, sometimes referred to as “layer select lines LL”).

Note that the word line select lines LW are connected to a plurality of the transistors TrL corresponding to the plurality of memory layers ML. Moreover, the respective layer select lines LLa are commonly connected to all of the transistors TrLa corresponding to the plurality of memory layers ML. Similarly, the respective layer select lines LLb are commonly connected to all of the transistors TrLb corresponding to the plurality of memory layers ML.

The transistor layer TL comprises: a plurality of bit line select lines LB0-LB2 (hereafter, sometimes referred to as “bit line select lines LB”); and pluralities of transistors TrB connected to the plurality of bit line select lines LB0-LB2. One electrode of the transistor TrB is connected to the global bit line GBL via an electrode Cn1. The other electrode of the transistor TrB is connected to the bit line BL. Note that the one and other electrodes of the transistor TrB function as a source electrode or a drain electrode, according to a voltage applied to the transistor TrB. A gate electrode of the transistor TrB is connected to any of the bit line select lines LB0-LB2.

The plurality of bit line select lines LB0-LB2 are each connected, via the first bonding electrode P_{I1} and the second bonding electrode P_{I2} (FIG. 1), to a drive circuit, or the like, provided in the chip C_{P}, for example.

### Structure of Chip C_{P}

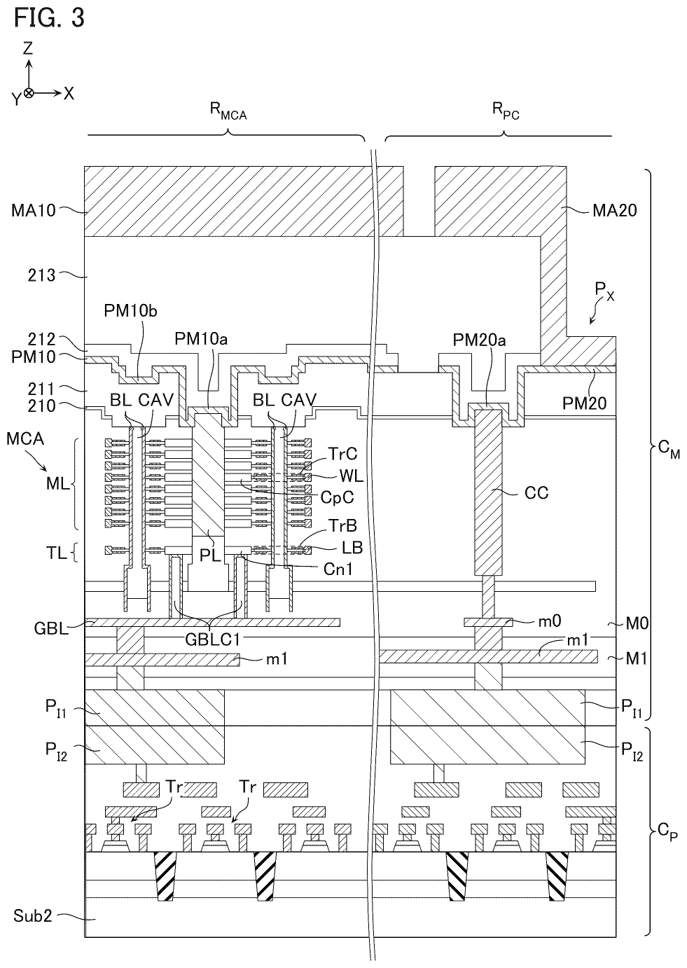

FIG. 3 is a schematic cross-sectional view showing a part of a configuration of the semiconductor memory device according to the present embodiment. FIG. 3 shows structure of parts of the chip C_{M} and the chip C_{P}.

In the chip C_{P} (FIG. 3), a plurality of transistors Tr, wirings, and so on, are provided on a substrate Sub2 of the likes of silicon (Si), for example. These plurality of transistors Tr, wirings, and so on, configure a control circuit, drive circuit, and so on, for controlling the memory cell array MCA. For example, the control circuit includes a sense amplifier circuit. The sense amplifier circuit is electrically connected to the bit line BL provided in the chip C_{M}, via the second bonding electrode P_{I2}, the first bonding electrode P_{I1}, and the global bit line GBL. The sense amplifier circuit is capable of detecting voltage fluctuation or current of the bit line BL in a read operation, and thereby reading data stored in a selected memory cell MC in the read operation.

### Structure of Chip C_{M}

The chip C_{M} (FIG. 3) comprises a region R_{MCA} and a region R_{PC}. Lower portions of the region R_{MCA} and the region R_{PC} are provided with: a wiring layer M0 including the global bit line GBL, a wiring m0, and so on; a wiring layer M1 including a wiring m1, and so on; and the first bonding electrode P_{I1}. Upper portions of the region R_{MCA} and the region R_{PC} are provided with: an insulating layer 210 of the likes of silicon nitride (SiN); and insulating layers 211, 212, 213 of the likes of silicon oxide (SiO₂).

### Structure of Region R_{MCA}

The region R_{MCA} is provided with the likes of the memory cell array MCA and a conductive layer MA10 above the memory cell array MCA.

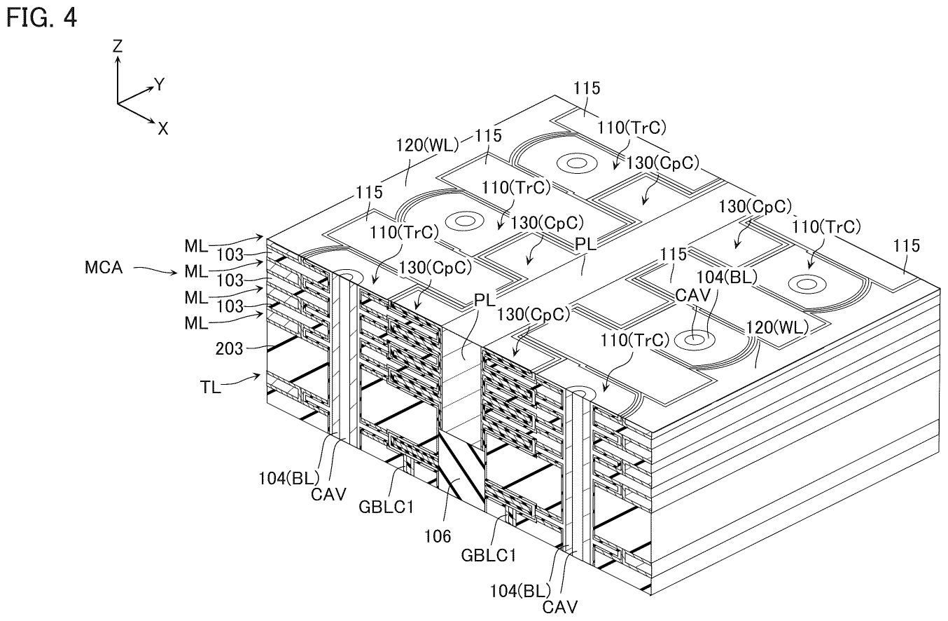

FIG. 4 is a schematic perspective view showing a part of a configuration of the semiconductor memory device according to the present embodiment. FIG. 4 shows structure of a part of the memory cell array MCA provided in the chip C_{M}.

Note that in the following description of the memory cell array MCA, expressions such as “above” or “below” will be defined with reference to the global bit lines GBL. For example, an orientation of moving away from the global bit lines GBL along the above-described Z-direction will be referred to as above, and an orientation of coming closer to the global bit lines GBL along the Z-direction will be referred to as below. Moreover, when an upper surface or an upper end is referred to for a certain configuration, this will be assumed to mean a surface or end portion on an opposite side to a global bit lines GBL side of this configuration, and when a lower surface or a lower end is referred to for a certain configuration, this will be assumed to mean a surface or end portion on the global bit lines GBL side of this configuration. Moreover, a surface intersecting the X-direction or the Y-direction will be referred to as a side surface, and so on.

As shown in FIGS. 3 and 4, for example, the memory cell array MCA comprises: the plurality of memory layers ML stacked in the Z-direction; the transistor layer TL provided between the memory layers ML and the global bit line GBL; and a conductive layer PM10 provided on an opposite side to the global bit line GBL with respect to the plurality of memory layers ML. Length in the Z-direction of the memory layer ML and length in the Z-direction of the transistor layer TL are about the same as each other.

Respective insulating layers 103 of the likes of silicon oxide (SiO₂) are provided between the plurality of memory layers ML. Moreover, an insulating layer 203 of the likes of silicon oxide (SiO₂) is provided between the memory layer ML first from below and the transistor layer TL. Length in the Z-direction of the insulating layer 203 is greater than length in the Z-direction of the insulating layer 103.

### Structure of Memory Layer ML and Transistor Layer TL

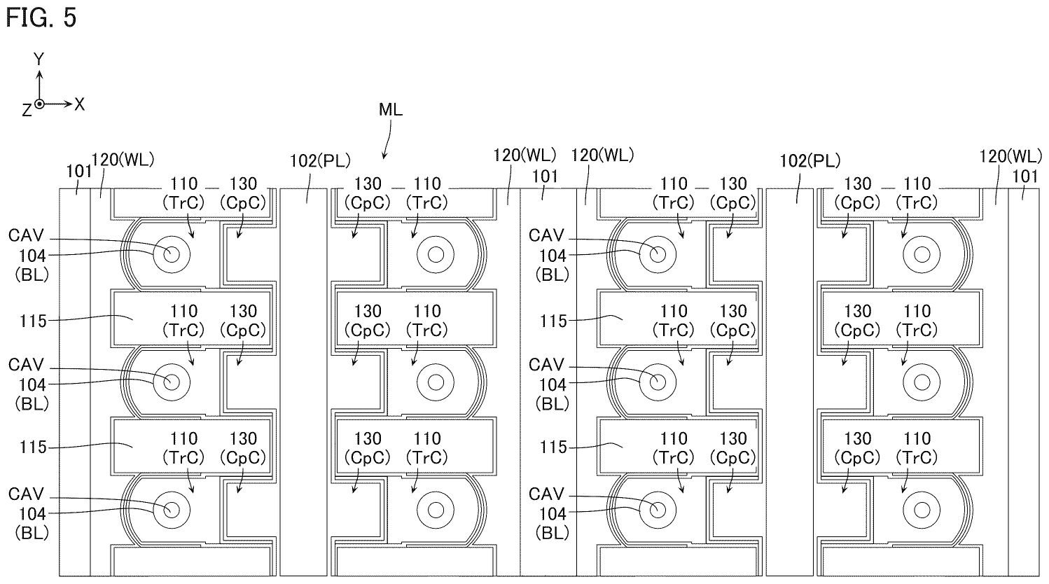

Next, structure of the memory layer ML and the transistor layer TL will be described with reference to FIGS. 5 to 11, in addition to FIGS. 3 and 4.

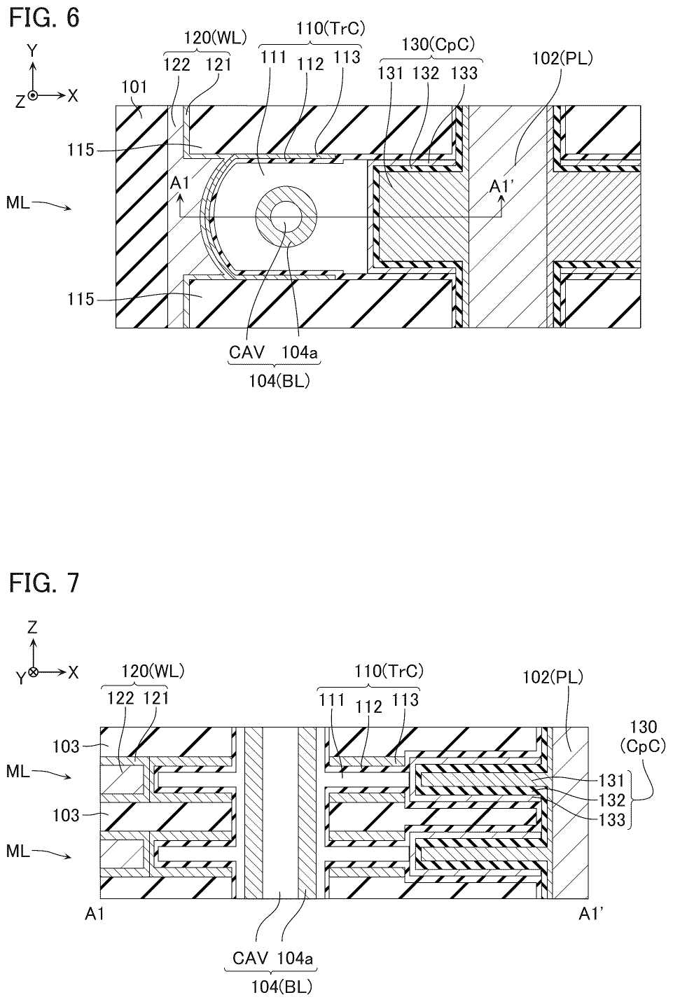

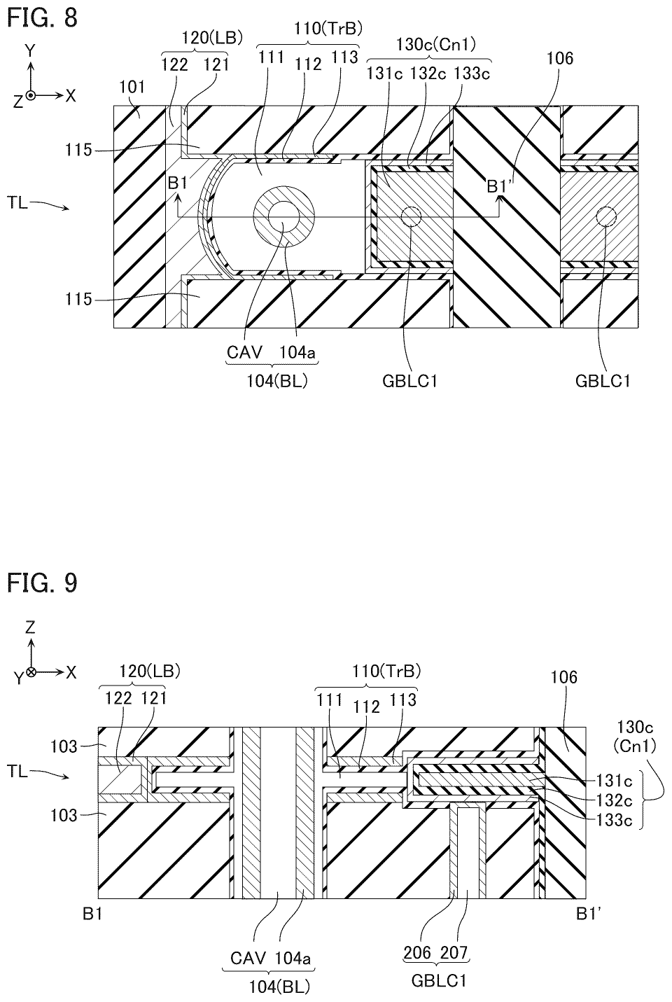

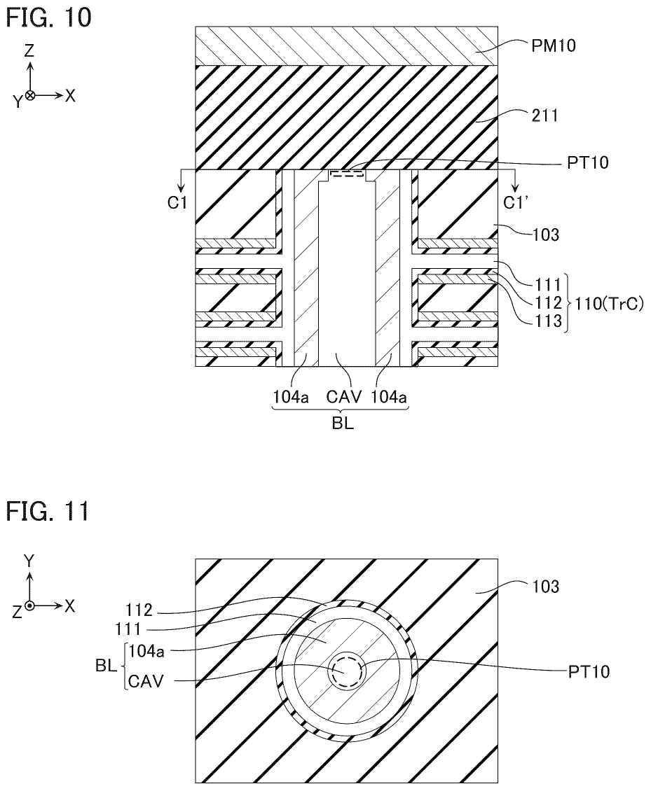

FIG. 5 is a schematic cross-sectional view showing a part of a configuration of the memory layer ML. FIG. 6, which is a schematic cross-sectional view showing a part of a configuration of the memory layer ML, shows an enlarged part of FIG. 5. FIG. 7 shows a cross section of the structure shown in FIG. 6 taken along the line A1-A1′ and viewed along a direction of the arrows. FIG. 8 is a schematic cross-sectional view showing a part of a configuration of the transistor layer TL. FIG. 9 shows a cross section of the structure shown in FIG. 8 taken along the line B1-B1′ and viewed along a direction of the arrows. FIG. 10 is a schematic cross-sectional view showing a part of a configuration of the bit line BL. FIG. 11 shows a cross section of the structure shown in FIG. 10 taken along the line C1-C1′ and viewed along a direction of the arrows.

As shown in FIG. 5, the memory layer ML is provided with a plurality of insulating layers 101 arranged in the X-direction, and a conductive layer 102 provided between two insulating layers 101 adjacent in the X-direction. The insulating layer 101 and the conductive layer 102 extend in the Y-direction and the Z-direction, and divide the plurality of memory layers ML in the X-direction.

The insulating layer 101 includes the likes of silicon oxide (SiO₂), for example.

The conductive layer 102 includes the likes of a stacked structure of titanium nitride (TiN) and tungsten (W), for example. Note that the conductive layer 102 may include a stacked structure of titanium nitride (TiN) and silicon germanium (SiGe), or may include a stacked structure of titanium nitride (TiN), silicon germanium (SiGe), and tungsten (W), for example. The conductive layer 102 functions as the plate line PL (FIG. 2), for example.

A region between the insulating layer 101 and the conductive layer 102 is provided with a plurality of via wirings 104 (FIG. 5). The plurality of via wirings 104 are arranged in the Y-direction, and as shown in FIG. 4, for example, extend in the Z-direction penetrating the transistor layer TL and the plurality of memory layers ML.

As shown in FIGS. 7 and 9, the via wiring 104 comprises a conductive oxide film 104a extending in the Z-direction, and a later-mentioned inner region CAV, for example. The via wiring 104 functions as the bit line BL (FIG. 2), for example. As shown in FIGS. 3 to 5, for example, a plurality of the bit lines BL are provided correspondingly to the pluralities of transistors TrC included in the memory layers ML and to the transistors TrB included in the transistor layer TL.

The conductive oxide film 104a comprises a substantially cylindrical shape extending in the Z-direction. The conductive oxide film 104a functions as a conductive member of the via wiring 104, for example. The conductive oxide film 104a includes the likes of indium tin oxide (ITO), for example.

The memory layer ML and the transistor layer TL comprise: a plurality of transistor structures 110 provided correspondingly to the plurality of via wirings 104; and a conductive layer 120 provided on an opposite side to the conductive layer 102 with respect to the plurality of transistor structures 110. In addition, the memory layer ML comprises a plurality of capacitor structures 130, that are provided between the plurality of transistor structures 110 and the conductive layer 102. In addition, the transistor layer TL (FIG. 9) comprises an electrode structure 130c, that is provided between the plurality of transistor structures 110 and a plurality of contacts GBLC1.

As shown in FIGS. 6 to 9, for example, the transistor structure 110 comprises: a semiconductor layer 111 connected to an outer peripheral surface of the via wiring 104 and extending in the X-direction; an insulating layer 112 provided on an upper surface, a lower surface, both side surfaces in the Y-direction, and a side surface on one side in the X-direction (a conductive layer 120 side) of the semiconductor layer 111; and a conductive layer 113 provided on an upper surface, a lower surface, both side surfaces in the Y-direction, and a side surface on one side in the X-direction (the conductive layer 120 side) of the insulating layer 112.

In an XY cross section of the kind exemplified in FIGS. 6 and 8, a side surface on one side in the X-direction (the conductive layer 120 side) of the semiconductor layer 111 may be formed along a circle centered on a center position of the via wiring 104. Moreover, side surfaces on the other side in the X-direction (a conductive layer 102 side) of the semiconductor layer 111, the insulating layer 112, and the conductive layer 113 may be formed linearly along a side surface of the conductive layer 102. Moreover, both side surfaces in the Y-direction of the semiconductor layer 111, the insulating layer 112, and the conductive layer 113 may be formed linearly along a side surface of an insulating layer 115.

The semiconductor layer 111 functions as a channel region of the transistors TrC, TrB (FIG. 2), for example. The semiconductor layer 111 may be, for example, a semiconductor including: at least one element of gallium (Ga) and aluminum (Al); indium (In); zinc (Zn); and oxygen (O), or may be, for example, another oxide semiconductor. A plurality of the semiconductor layers 111 arranged in the Z-direction are commonly connected to the via wiring 104 extending in the Z-direction.

The insulating layer 112 functions as a gate insulating film of the transistors TrC, TrB (FIG. 2), for example. The insulating layer 112 includes the likes of silicon oxide (SiO₂), for example.

The conductive layer 113 functions as the gate electrode of the transistors TrC, TrB (FIG. 2), for example. The conductive layer 113 includes titanium nitride (TiN) and a conductive oxide such as indium tin oxide (ITO), for example. A plurality of the conductive layers 113 arranged in the Y-direction are commonly connected to the conductive layer 120 extending in the Y-direction (refer to FIGS. 4 and 5). The conductive layer 113 faces the upper surface, the lower surface, both side surfaces in the Y-direction, and the side surface on one side in the X-direction (the conductive layer 120 side) of the semiconductor layer 111, via the insulating layer 112. Note that in the present specification, a “conductive oxide” includes indium tin oxide (ITO), indium zinc oxide (IZO), ruthenium oxide (RuO₂), iridium oxide (IrO₂), or another conductive material including oxygen, for example.

The insulating layer 115 of the likes of silicon oxide (SiO₂) is provided between two semiconductor layers 111 adjacent in the Y-direction. The insulating layer 115 extends in the Z-direction penetrating the transistor layer TL and the plurality of memory layers ML.

The conductive layer 120 functions as the word line WL in the memory layer ML, and as the bit line select line LB in the transistor layer TL (FIG. 2), for example. The conductive layer 120 extends in the Y-direction, and is connected to a plurality of the conductive layers 113 arranged in the Y-direction. As shown in FIGS. 6 and 8, for example, the conductive layer 120 is connected at its side surface on one side in the X-direction to the conductive layer 113, and contacts at its side surface on the other side in the X-direction the insulating layer 101. The conductive layer 120 comprises: a barrier conductive film 121 of the likes of titanium nitride (TiN), for example; and a conductive film 122 of tungsten (W). The barrier conductive film 121 is provided on an upper surface, a lower surface, and a side surface on one side in the X-direction (a transistor structure 110 side) of the conductive film 122.

As shown in FIGS. 6 and 7, for example, the capacitor structure 130 comprises: a conductive layer 131; an insulating layer 132 provided on an upper surface, a lower surface, both side surfaces in the Y-direction, and a side surface on one side in the X-direction (the transistor structure 110 side) of the conductive layer 131; and a conductive layer 133 provided on an upper surface, a lower surface, both side surfaces in the Y-direction, and a side surface on one side in the X-direction (the transistor structure 110 side) of the insulating layer 132.

The conductive layer 131 functions as one electrode of the capacitor CpC (FIG. 2). The conductive layer 131 includes the likes of a stacked structure of titanium nitride (TiN) and silicon germanium (SiGe), for example. Note that the conductive layer 131 may include a stacked structure of titanium nitride (TiN) and tungsten (W), or may include a stacked structure of titanium nitride (TiN), silicon germanium (SiGe), and tungsten (W), for example. One side in the X-direction of the conductive layer 131 contacts the conductive layer 102.

The insulating layer 132 functions as an insulating layer of the capacitor CpC (FIG. 2). The insulating layer 132 may be of zirconia (ZrO₂), alumina (Al₂O₃), or another insulating metal oxide, for example. Moreover, the insulating layer 132 may be for example a stacked film of a plurality of insulating metal oxides (for example, a stacked film of zirconia and alumina).

The conductive layer 133 functions as the other electrode of the capacitor CpC (FIG. 2), for example. The conductive layer 133 includes a conductive oxide such as indium tin oxide (ITO), for example. The conductive layer 133 is insulated from the conductive layer 131 via the insulating layer 132. The conductive layer 133 is connected to a side surface in the X-direction of the semiconductor layer 111. The conductive layer 133 is insulated from the conductive layer 102 via the insulating layer 132.

As shown in FIGS. 8 and 9, for example, the electrode structure 130c comprises: a conductive layer 131c; an insulating layer 132c provided on an upper surface, a lower surface, both side surfaces in the Y-direction, and a side surface on one side in the X-direction (the transistor structure 110 side) of the conductive layer 131c; and a conductive layer 133c provided on an upper surface, a lower surface, both side surfaces in the Y-direction, and a side surface on one side in the X-direction (the transistor structure 110 side) of the insulating layer 132c.

The conductive layer 131c includes a similar material to the conductive layer 131. One side in the X-direction (the conductive layer 102 side) of the conductive layer 131c contacts an insulating layer 106 of the likes of silicon oxide (SiO₂).

The insulating layer 132c includes a similar material to the insulating layer 132. One side in the X-direction (the conductive layer 102 side) of the insulating layer 132c contacts the insulating layer 106.

The conductive layer 133c functions as a conductive member of the electrode Cn1 (FIG. 2), for example. The conductive layer 133c includes a similar material to the conductive layer 133. A side surface on one side in the X-direction (the transistor structure 110 side) of the conductive layer 133c is connected to a side surface in the X-direction of the semiconductor layer 111. A side surface on the other side in the X-direction (an insulating layer 106 side) of the conductive layer 133c contacts the insulating layer 106.

The contact GBLC1 is provided below the electrode structure 130c (FIGS. 3, 4, and 9). As shown in FIG. 9, for example, the contact GBLC1 comprises: a conductive film 206 of the likes of indium tin oxide (ITO); and an insulating film 207 of the likes of silicon oxide (SiO₂). The contact GBLC1 is connected at its upper surface to a lower surface of the conductive layer 133c included in the electrode structure 130c. The contact GBLC1 is connected at its lower surface to the global bit line GBL (FIG. 3). The contact GBLC1 functions as an electrode for connecting the transistor TrB to the global bit line GBL via the electrode Cn1, for example.

A plurality of the global bit lines GBL, each extending in the X-direction as shown in FIG. 3, for example, are provided arranged in the Y-direction. The global bit lines GBL may be arranged in the Y-direction with a pitch equal to a pitch that the transistor structures 110 are arranged in the Y-direction (FIG. 5). The global bit line GBL comprises a barrier conductive film of the likes of titanium nitride (TiN), and a conductive film of the likes of tungsten (W), for example.

The conductive layer PM10 (FIG. 3) includes a portion PM10a (FIG. 3) connected to the plate line PL (conductive layer 102). The conductive layer PM10 functions as a wiring for connecting a plurality of the plate lines PL (FIG. 5) arranged in the X-direction, for example. The conductive layer PM10 (FIG. 3) includes a stacked structure of titanium nitride (TiN) and tungsten (W), for example.

In addition, the conductive layer PM10 (FIG. 3) includes a portion PM10b (FIG. 3) at a position overlapping the via wiring 104 viewed in the Z-direction. The conductive layer PM10 functions as a layer for preventing hydrogen (H) from diffusing into the plurality of memory layers ML and the transistor layer TL in a later-mentioned manufacturing step, for example.

The conductive layer MA10 is provided above the conductive layer PM10 via the insulating layers 212, 213. The conductive layer MA10 includes the likes of a stacked structure of titanium nitride (TiN) and aluminum (Al), for example.

### Structure of Region R_{PC}

The region R_{PC} is provided with the likes of a contact CC, a conductive layer PM20 connected to an upper end portion of the contact CC, and a conductive layer MA20 connected to an upper surface of the conductive layer PM20.

The contact CC (FIG. 3) extends in the Z-direction. The contact CC is connected downwardly thereof to the wiring m0 included in the wiring layer M0, and is electrically connected to the first bonding electrode P_{I1} via the wirings m0, m1, and so on. The contact CC includes a stacked structure of titanium nitride (TiN) and tungsten (W), for example.

The conductive layer PM20 includes a portion PM20a (FIG. 3) connected to the contact CC. The conductive layer PM20 functions as a wiring for connecting the contact CC to the conductive layer MA20, for example. The conductive layer PM20 (FIG. 3) includes a similar material to the conductive layer PM10, for example.

A portion connected to the conductive layer PM20 of the conductive layer MA20 functions as the external pad electrode P_{X} (FIG. 1), for example. The conductive layer MA20 (FIG. 3) includes a similar material to the conductive layer MA10, for example.

### Details of Inner Region CAV

Next, details of the inner region CAV will be described with reference to FIGS. 10 and 11. FIGS. 10 and 11 are schematic cross-sectional views showing configurations of an end portion of the bit line BL. FIG. 11 shows a cross section of the structure shown in FIG. 10 taken along the line C1-C1′ and viewed along a direction of the arrows. Note that hereafter, an end portion on an opposite side to the global bit line GBL with respect to the memory layers ML in the Z-direction, within the inner region CAV will sometimes be referred to as an upper end portion PT10 of the inner region CAV.

As shown in FIGS. 10 and 11, for example, the inner region CAV comprises a substantially circular column-like shape extending in the Z-direction. An outer peripheral surface of the inner region CAV is surrounded by the conductive oxide film 104a, for example.

The upper end portion PT10 (FIGS. 10 and 11) of the inner region CAV is not covered by the conductive oxide film 104a. The upper end portion PT10 of the inner region CAV is covered by the insulating layer 211, for example.

The upper end portion PT10 of the inner region CAV may contact the insulating layer 211, as shown in FIG. 10.

Note that a part of the insulating layer 211 may be formed so as to partly enter inside the cylindrically shaped conductive oxide film 104a. In such a case, the upper end portion of the inner region CAV will be continuous with the insulating layer 211.

The inner region CAV may be a cavity, for example. Note that cavity indicates a so-called space surrounded by a solid material disposed in a periphery of a portion where the cavity is present, and the portion where the cavity is present does not include any kind of solid material. The cavity is a space including the likes of air consisting of a mixture of a plurality of gases such as nitrogen, oxygen, and a rare gas, for example. Note that the cavity may be degassed so as to not include any kind of gas.

The inner region CAV may include an insulating layer of the likes of silicon oxide (SiO₂) or silicon nitride (SiN), for example.

The inner region CAV may be provided extending in the Z-direction from the transistor layer TL provided at a position closest to the global bit line GBL, to the memory layer ML provided at a position furthest from the global bit line GBL, as shown in FIG. 3, for example. Moreover, the inner region CAV may be provided extending in the Z-direction from the memory layer ML provided at a position closest to the global bit line GBL, to the memory layer ML provided at a position furthest from the global bit line GBL.

### Method of Manufacturing

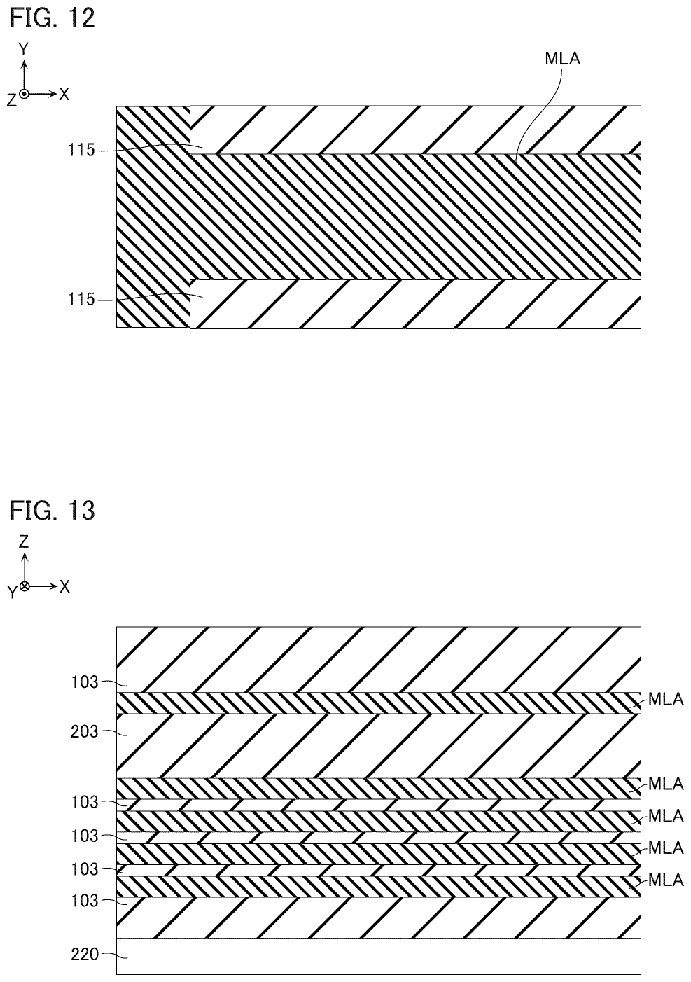

FIGS. 12 to 58 are schematic cross-sectional views for explaining a method of manufacturing the semiconductor memory device according to the first embodiment.

FIGS. 12, 14, 16, 18, 20, 22, 24, 26, 28, 30, 32, 34, 36, 38, and 40 show XY cross sections corresponding to FIG. 6.

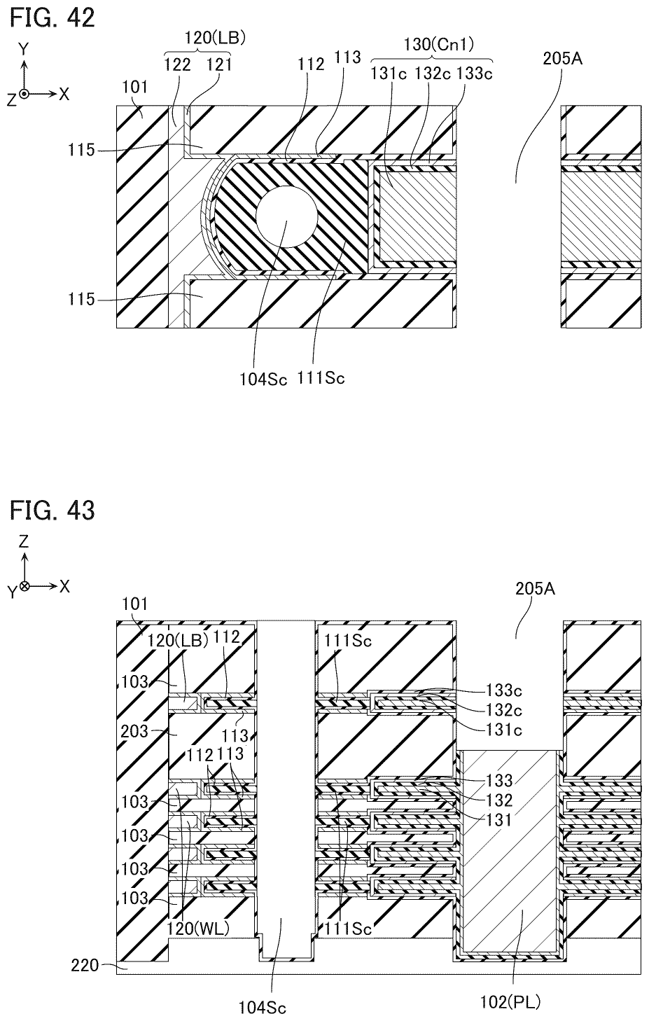

### FIGS. 42, 44, 46, and 48 Show Xy Cross Sections corresponding to FIG. 8.

FIGS. 13, 15, 17, 19, 21, 23, 25, 27, 29, 31, 33, 35, 37, 39, 41, 43, 45, 47, and 49 show XZ cross sections corresponding to parts of the memory layers ML and the transistor layer TL.

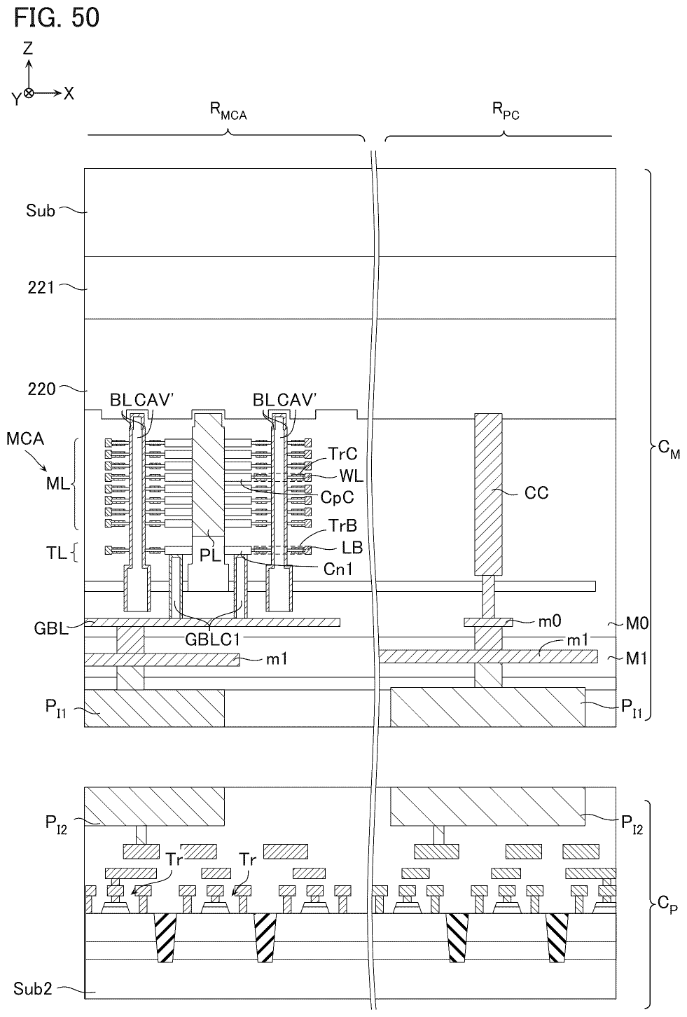

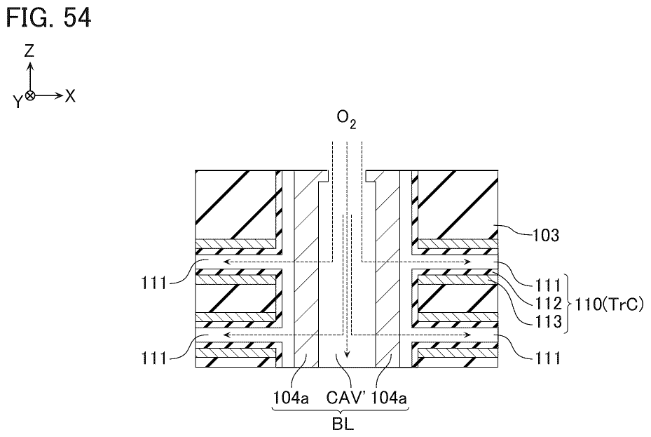

FIGS. 50 to 53, and FIGS. 55 to 58 show cross sections corresponding to FIG. 3. FIG. 54 shows a cross section with the end portion of the bit line enlarged.

Note that in FIGS. 12 to 49 describing manufacturing of the chip C_{M}, an orientation representing upwards in processes of same method of manufacturing is depicted as a positive side in the Z-direction, and an orientation representing downwards in processes of same method of manufacturing is depicted as a negative side in the Z-direction. For example, in FIGS. 12 to 49, the front surface of the chip C_{M} is depicted on an upper side (a positive side in the Z-direction), and the back surface of the chip C_{M} is depicted on a lower side (a negative side in the Z-direction). In FIGS. 50 to 58, the front surface and the back surface of the chip C_{M} have their vertical positional relationship reversed, with the front surface of the chip C_{M} being depicted on a lower side (a negative side in the Z-direction), and the back surface of the chip C_{M} being depicted on an upper side (a positive side in the Z-direction). In FIGS. 12 to 49, positive and negative orientations in the Z-direction differ from in the configurations described with reference to FIGS. 3 to 11. In FIGS. 50 to 58, positive and negative orientations in the Z-direction are the same as in the configurations described with reference to FIGS. 3 to 11.

In same method of manufacturing, an insulating layer 221 of the likes of silicon oxide (SiO₂), and a semiconductor layer 220 are formed on a substrate Sub (refer to FIG. 50). The substrate Sub may be a semiconductor substrate of the likes of silicon (Si) including a P-type impurity such as boron (B), or may be a substrate including another impurity and material, for example. The semiconductor layer 220 may be of the likes of polysilicon (p-Si), for example.

Next, as shown in FIGS. 12 and 13, for example, the plurality of insulating layers 103 and the insulating layer 203, and a plurality of sacrifice layers MLA, are alternately formed above the semiconductor layer 220. The sacrifice layer MLA includes the likes of silicon nitride (SiN), for example. This step is performed by the likes of CVD (Chemical Vapor Deposition), for example.

Next, as shown in FIG. 12, for example, the insulating layer 115 is formed. In this step, for example, an opening is formed at a position corresponding to the insulating layer 115. This opening extends in the Z-direction, penetrates the plurality of insulating layers 103, the insulating layer 203, and the plurality of sacrifice layers MLA stacked in the Z-direction, and exposes the semiconductor layer 220. This step is performed by the likes of RIE (Reactive Ion Etching), for example. After formation of the opening, the insulating layer 115 is formed in the opening. This step is performed by the likes of CVD, for example.

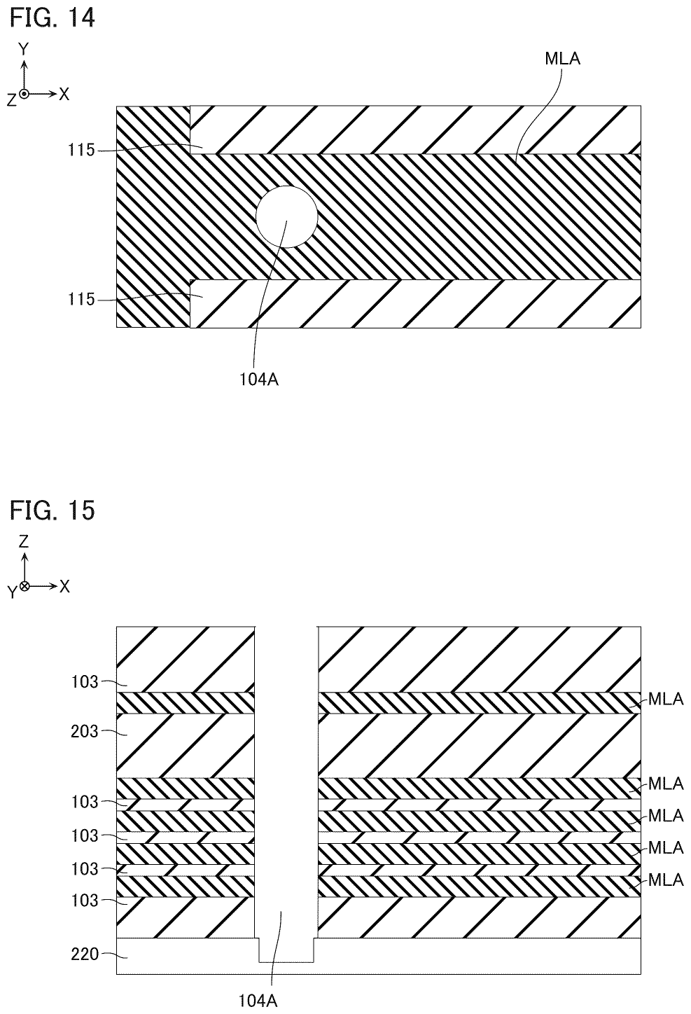

Next, as shown in FIGS. 14 and 15, for example, an opening 104A is formed at a position corresponding to the via wiring 104. As shown in FIGS. 14 and 15, the opening 104A extends in the Z-direction, penetrates the plurality of insulating layers 103, the insulating layer 203, and the plurality of sacrifice layers MLA stacked in the Z-direction, and exposes the semiconductor layer 220. This step is performed by the likes of RIE, for example.

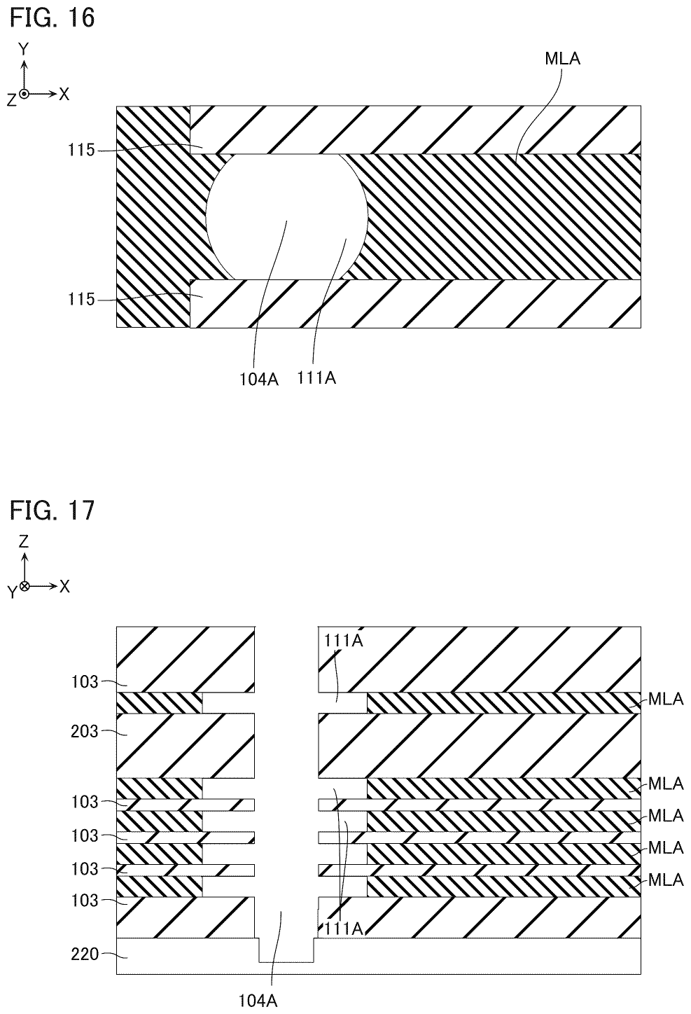

Next, as shown in FIGS. 16 and 17, for example, an opening 111A is formed. Parts of upper surfaces and parts of lower surfaces of the insulating layers 103, 203, and parts of side surfaces in the X-direction of the sacrifice layer MLA are exposed in the opening 111A. In this step, for example, parts of the sacrifice layer MLA are selectively removed via the opening 104A. This step is performed by the likes of wet etching, for example.

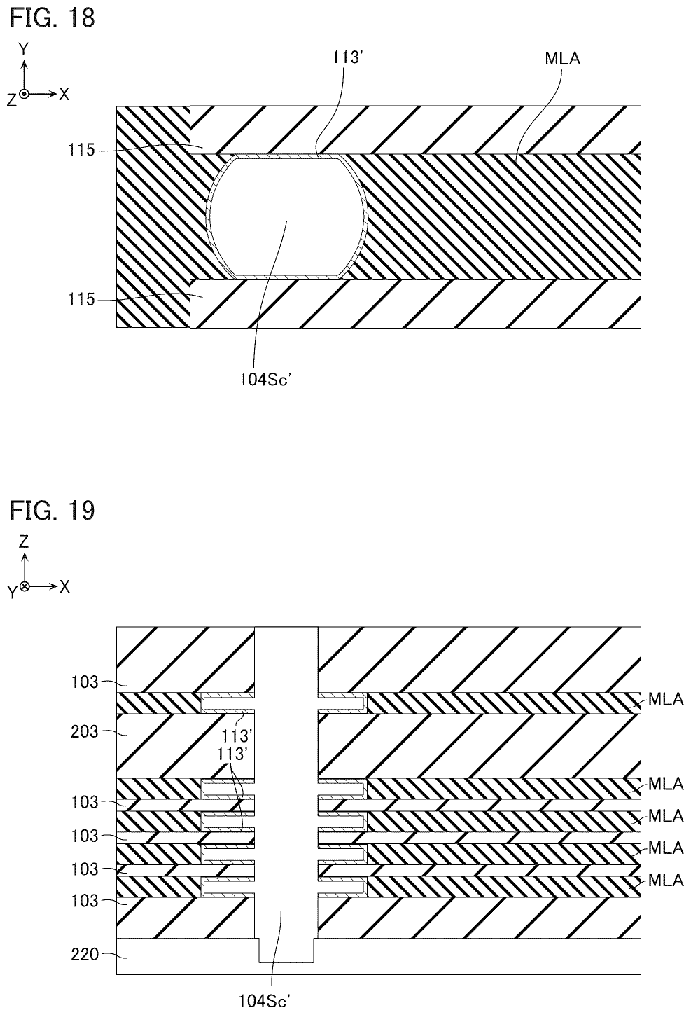

Next, as shown in FIGS. 18 and 19, for example, a conductive layer 113′ is formed inside the opening 111A, and a sacrifice layer 104Sc′ is formed inside the openings 104A, 111A. In this step, for example, a conductive film of the likes of titanium nitride (TiN) is formed inside the openings 104A, 111A. Next, on the inside of the opening 104A, parts (portions formed on side surfaces of the insulating layers 103, 203) of the conductive film are removed, and the conductive film divided in the Z-direction, whereby the conductive layers 113′ are formed. Next, silicon (Si), or the like, is filled in to the openings 104A, 111A, and the sacrifice layer 104Sc′ formed. This step is performed by the likes of CVD and RIE, for example.

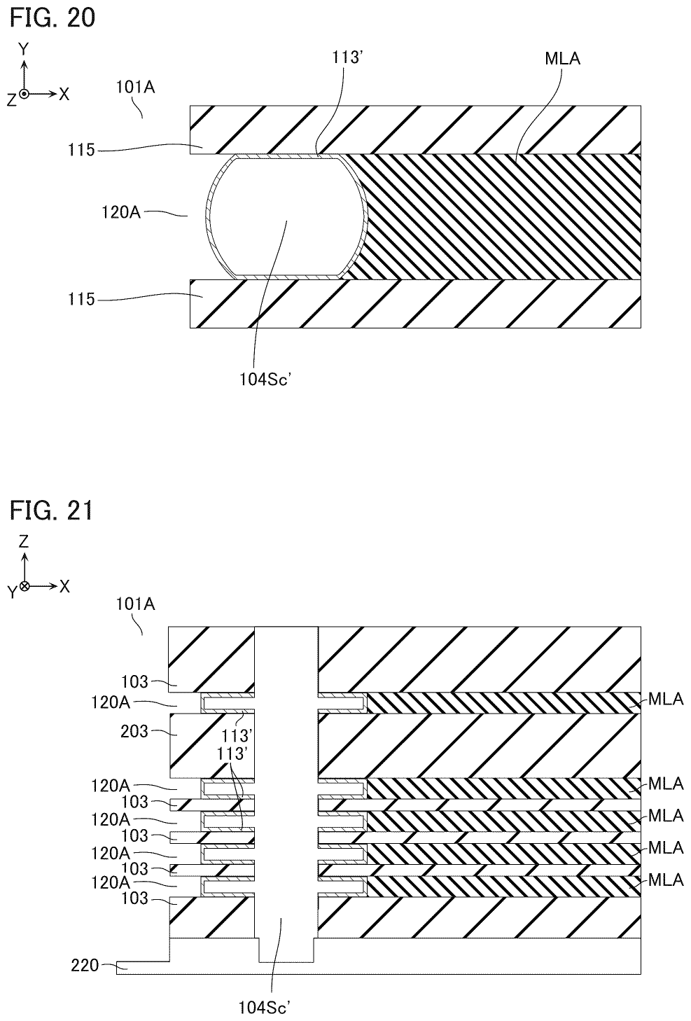

Next, as shown in FIGS. 20 and 21, for example, an opening 101A and opening 120A are formed at positions corresponding to the insulating layer 101 and the conductive layer 120. Parts of the upper surfaces and parts of the lower surfaces of the insulating layers 103, 203, and a side surface in the X-direction of the conductive layer 113′ are exposed in the opening 120A. In this step, for example, the opening 101A is formed, and then parts of the sacrifice layers MLA are selectively removed via the opening 101A. This step is performed by the likes of RIE and wet etching, for example.

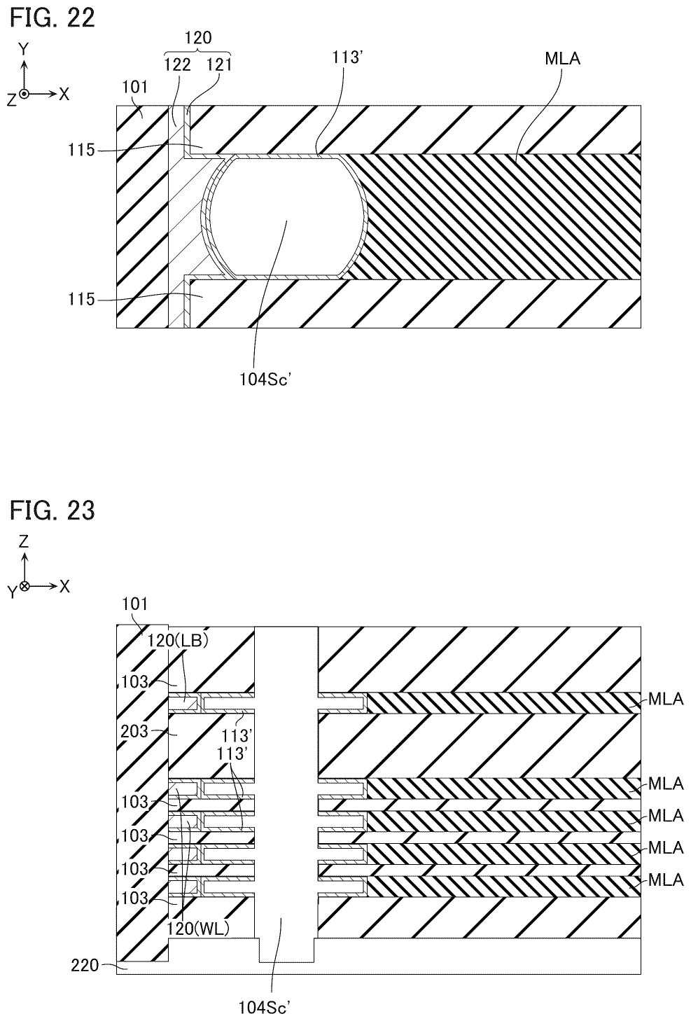

Next, as shown in FIGS. 22 and 23, for example, the conductive layer 120 and the insulating layer 101 are formed inside the opening 120A and the opening 101A. In this step, for example, a conductive film including a similar material to the conductive layer 120 is formed inside the openings 120A, 101A. Next, on the inside of the opening 101A, parts (portions formed on side surfaces of the insulating layers 103, 203) of the conductive film are removed, and the conductive film divided in the Z-direction, whereby the conductive layers 120 are formed. Next, the insulating layer 101 is filled in to the opening 101A. This step is performed by a method such as CVD and RIE, for example.

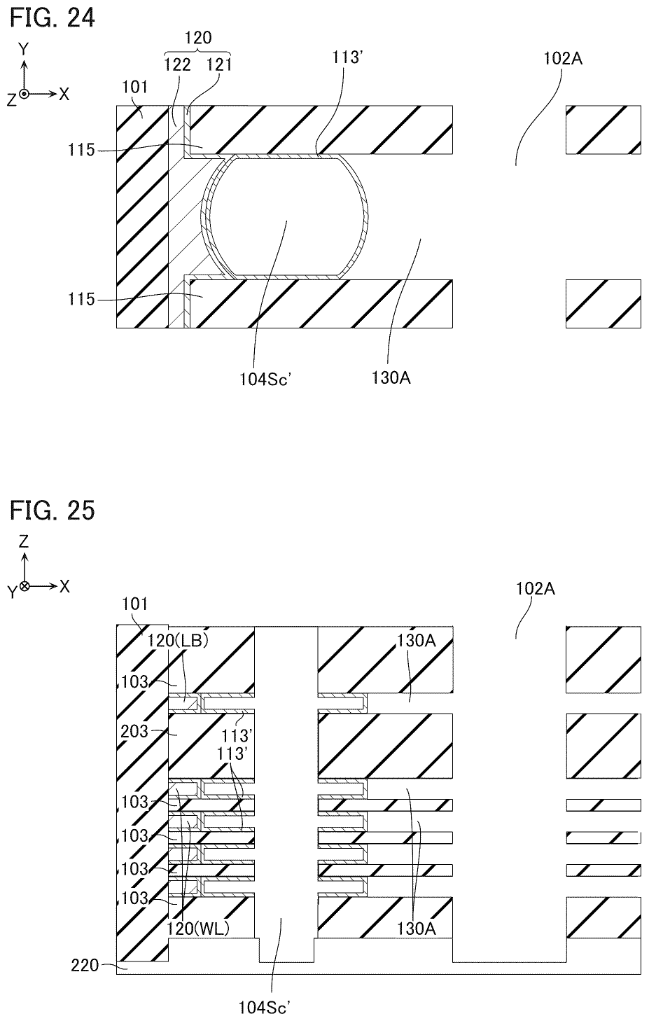

Next, as shown in FIGS. 24 and 25, for example, an opening 102A is formed at a position corresponding to the conductive layer 102 and the insulating layer 106. The opening 102A extends in the Z-direction, penetrates the plurality of insulating layers 103, the insulating layer 203, and the plurality of sacrifice layers MLA stacked in the Z-direction, and exposes the semiconductor layer 220. This step is performed by the likes of RIE, for example.

In addition, as shown in FIGS. 24 and 25, for example, an opening 130A is formed. Parts of the upper surfaces and parts of the lower surfaces of the insulating layers 103, 203, and a part of a side surface in the X-direction of the conductive layer 113′ are exposed in the opening 130A. In this step, for example, parts of the sacrifice layers MLA are selectively removed via the opening 102A. This step is performed by the likes of wet etching, for example.

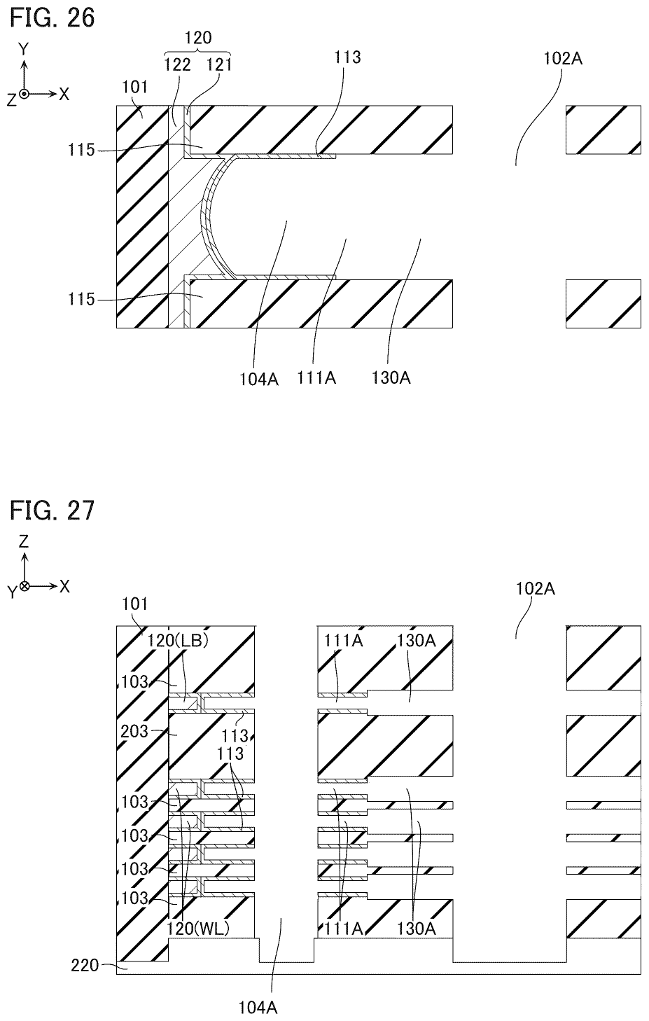

Next, as shown in FIGS. 26 and 27, for example, the parts of the upper surfaces and parts of the lower surfaces of the insulating layers 103, 203, and the part of the side surface in the X-direction of the conductive layer 113′ that have been exposed in the opening 130A, are removed. This step causes width in the Z-direction of the opening 130A to increase. This step is performed by the likes of wet etching, for example.

In addition, as shown in FIGS. 26 and 27, for example, the sacrifice layer 104Sc′ is removed, and the openings 104A, 111A formed. This step causes the openings 102A, 104A, 111A, 130A to communicate. This step is performed by the likes of wet etching, for example.

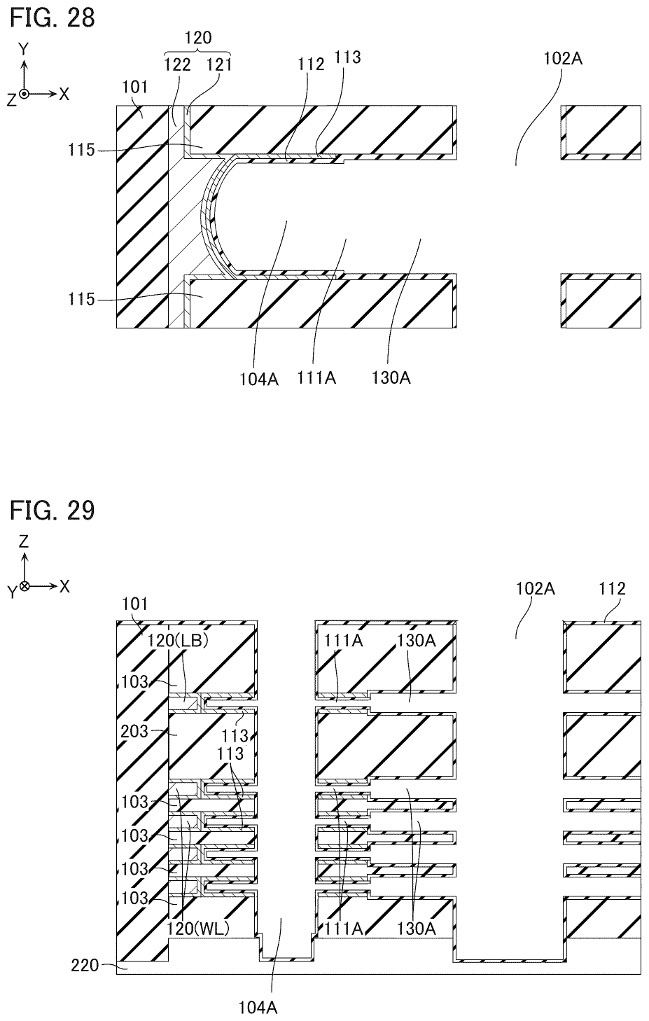

Next, as shown in FIGS. 28 and 29, for example, the insulating layer 112 is formed inside the openings 102A, 104A, 111A, 130A. This step is performed by the likes of CVD, for example.

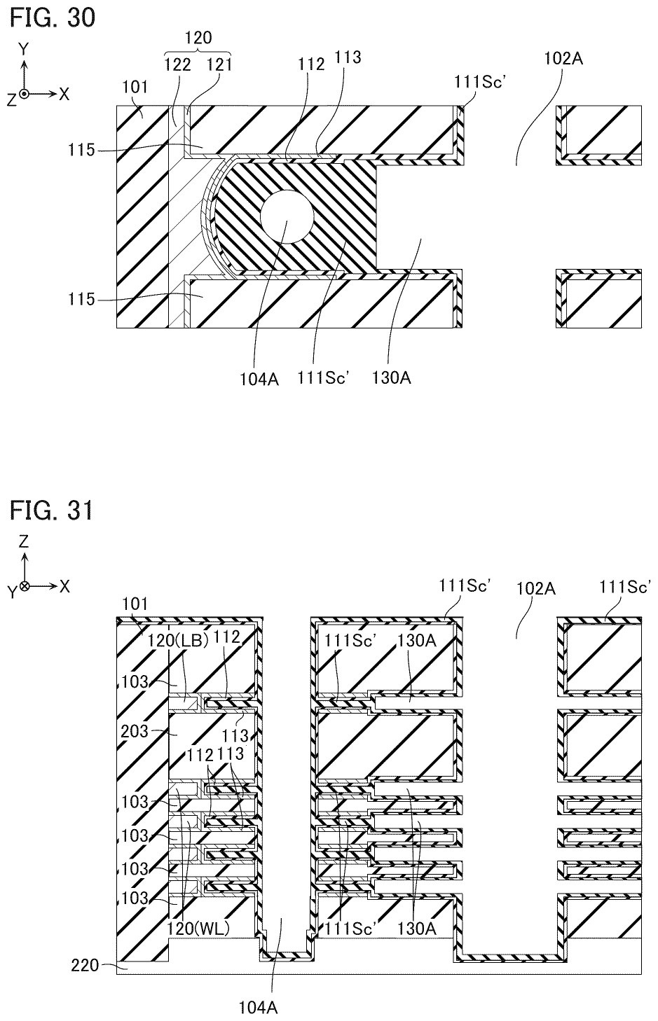

Next, as shown in FIGS. 30 and 31, for example, a sacrifice layer 111Sc′ of the likes of silicon nitride (SiN) or titanium nitride (TiN) is formed inside the openings 102A, 104A, 111A, 130A, via the opening 102A and opening 104A. In this step, the opening 111A is filled in by the sacrifice layer 111Sc′, but the openings 102A, 104A, 130A are not filled in by the sacrifice layer 111Sc′. This step is performed by the likes of CVD, for example.

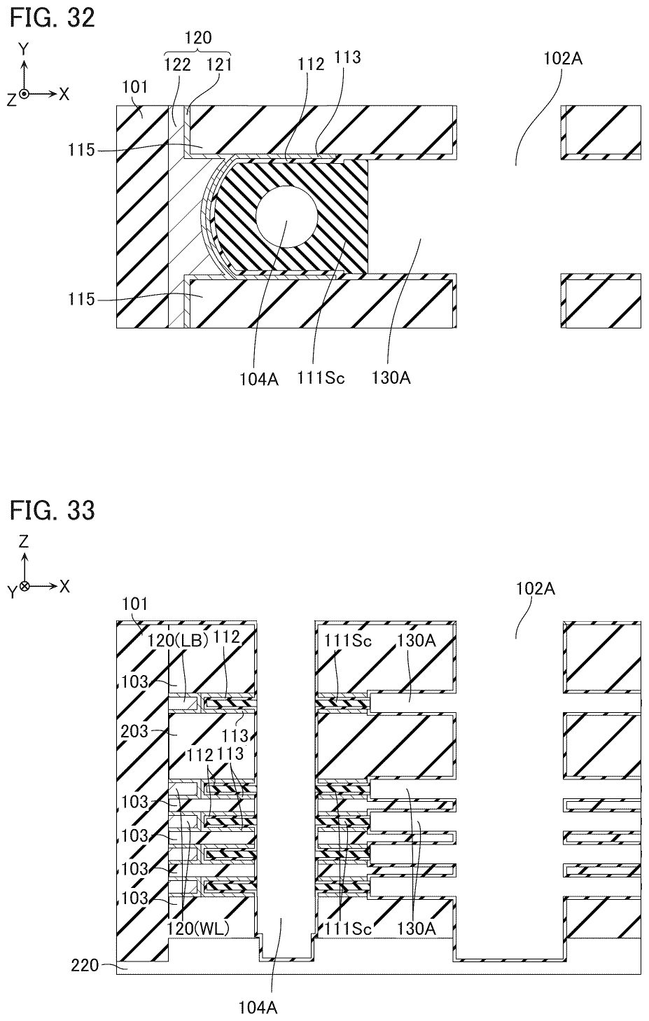

Next, as shown in FIGS. 32 and 33, for example, parts of the sacrifice layer 111Sc′ are removed and the sacrifice layer 111Sc′ divided in the Z-direction, via the openings 102A, 104A, whereby a sacrifice layer 111Sc of the likes of silicon nitride (SiN) or titanium nitride (TiN) is formed. This step is performed by the likes of wet etching, for example.

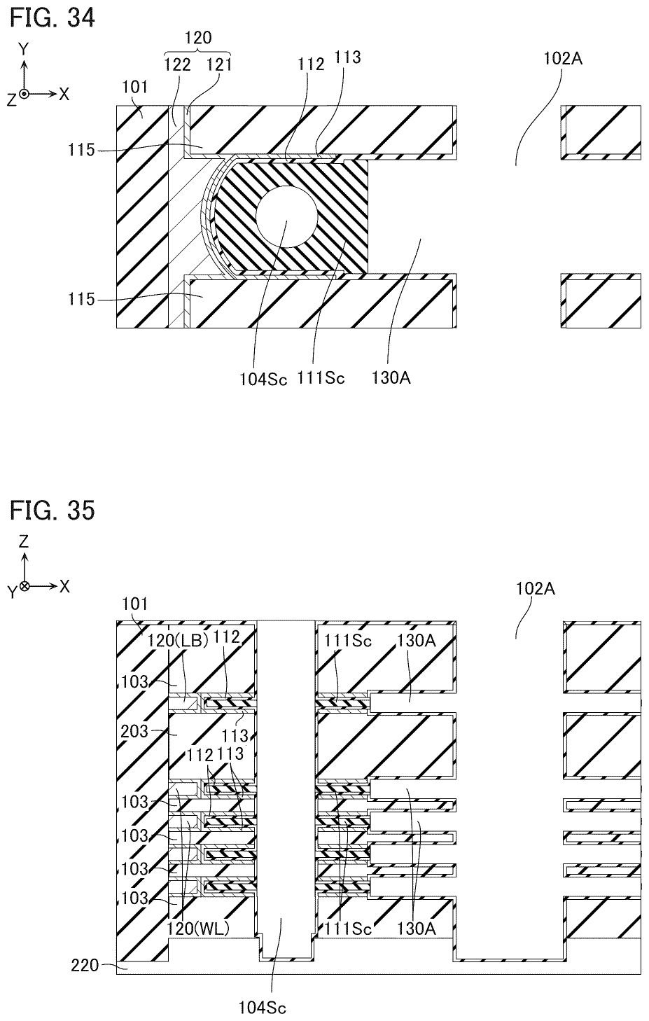

Next, as shown in FIGS. 34 and 35, for example, silicon (Si), or the like, is filled in to the opening 104A, and a sacrifice layer 104Sc formed. In this step, for example, silicon (Si), or the like, is filled in to the openings 102A, 104A, and the silicon (Si), or the like, that has been filled in to the opening 102a then removed. This step is performed by the likes of CVD and wet etching, for example.

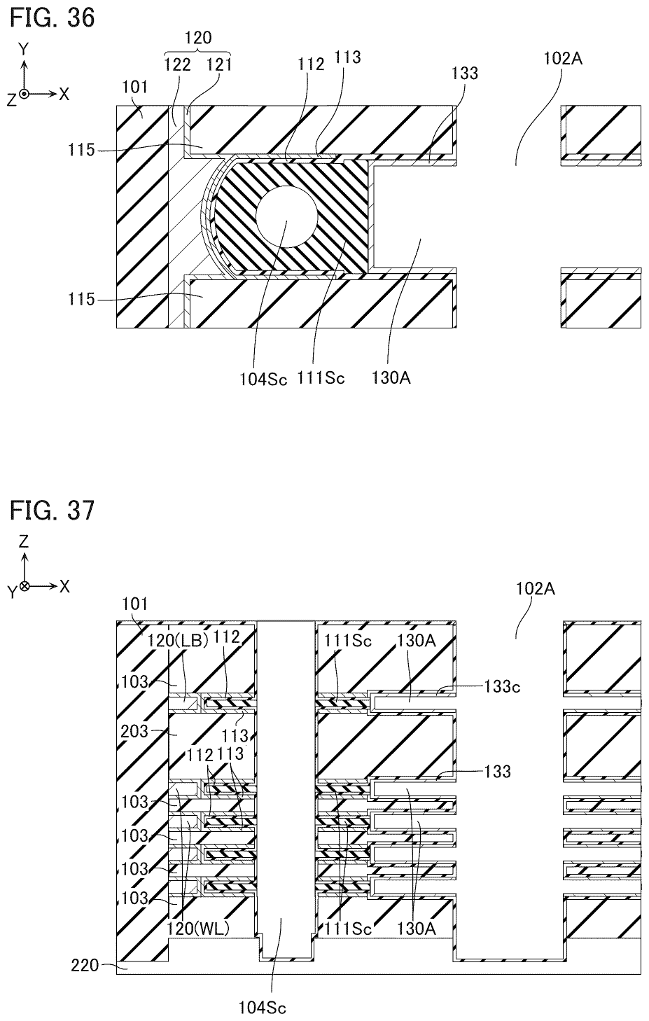

Next, as shown in FIGS. 36 and 37, for example, the conductive layers 133, 133c are formed inside the opening 130A. In this step, for example, a conductive oxide layer of the likes of indium tin oxide (ITO), for example, is formed inside the openings 120A, 130A. Next, on the inside of the opening 102A, parts (portions formed on side surfaces of the insulating layers 103, 203) of the conductive oxide layer are removed, and the conductive oxide layer divided in the Z-direction, whereby the conductive layers 133, 133c are formed. This step is performed by the likes of CVD and RIE, for example.

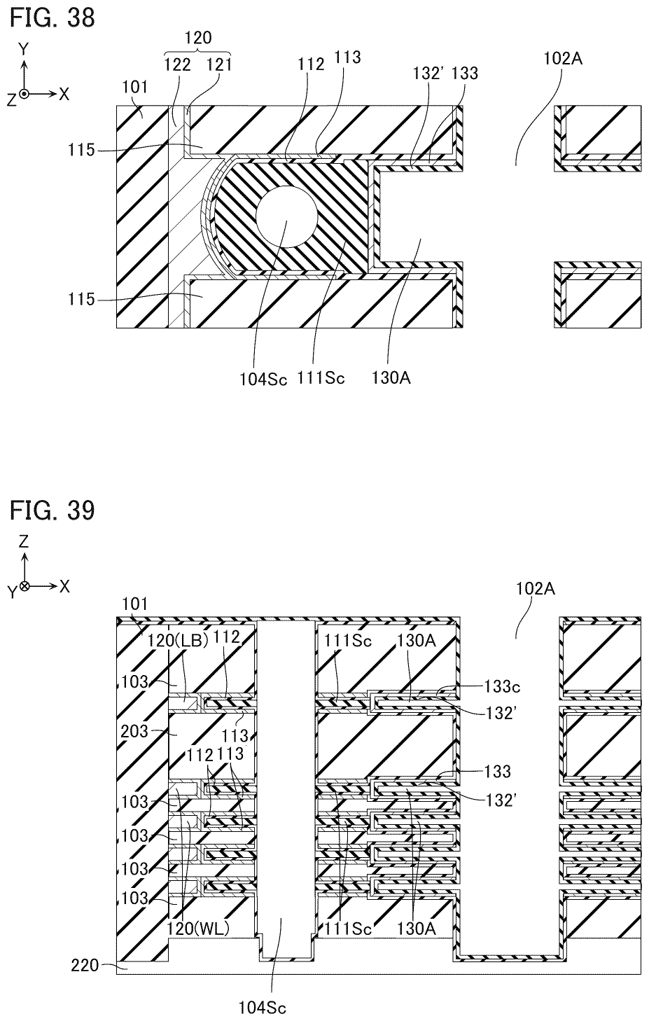

Next, as shown in FIGS. 38 and 39, for example, an insulating layer 132′ including a similar material to the insulating layer 132 is formed inside the openings 102A, 130A, and on an upper surface of the structure shown in FIG. 37. This step is performed by the likes of CVD, for example.

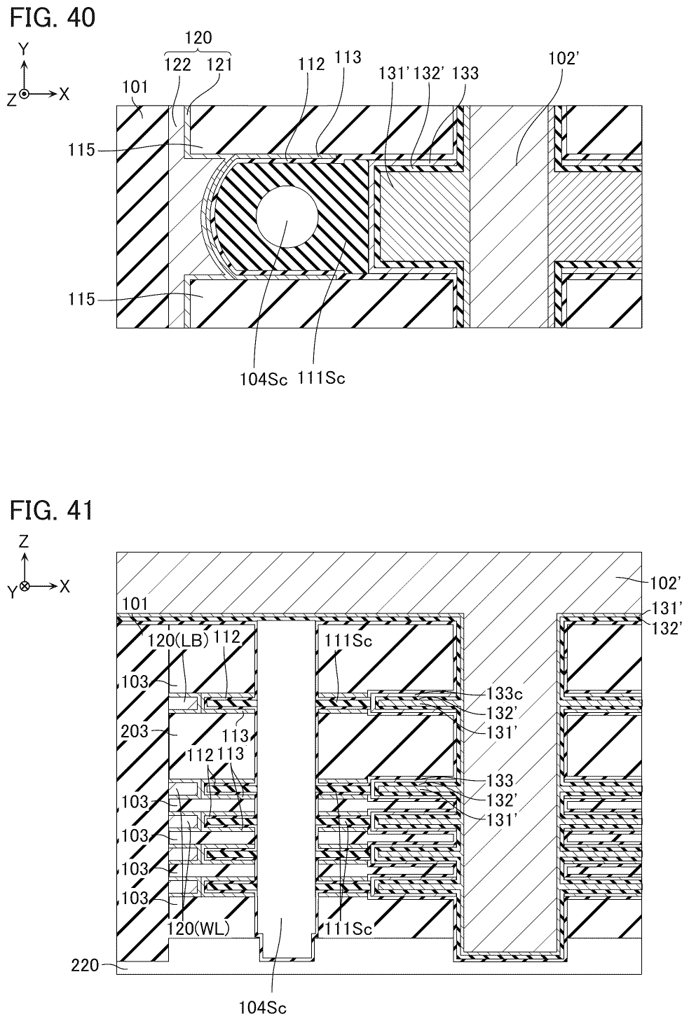

Next, as shown in FIGS. 40 and 41, for example, a conductive layer 131′ including a similar material to the conductive layer 131 is formed inside the openings 102A, 130A, following which a conductive layer 102′ including a similar material to the conductive layer 102 is formed inside the opening 102A. In this step, the opening 130A is filled in by the conductive layer 131', but the opening 102A is not filled in by the conductive layer 131′. This step is performed by the likes of CVD, for example.

Next, as shown in FIGS. 42 and 43, for example, parts of the conductive layer 102′, conductive layer 131′, and the insulating layer 132′ are removed, and the conductive layers 131, 131c, insulating layers 132, 132c, conductive layer 102, and an opening 205A formed. This step is performed by the likes of RIE, for example.

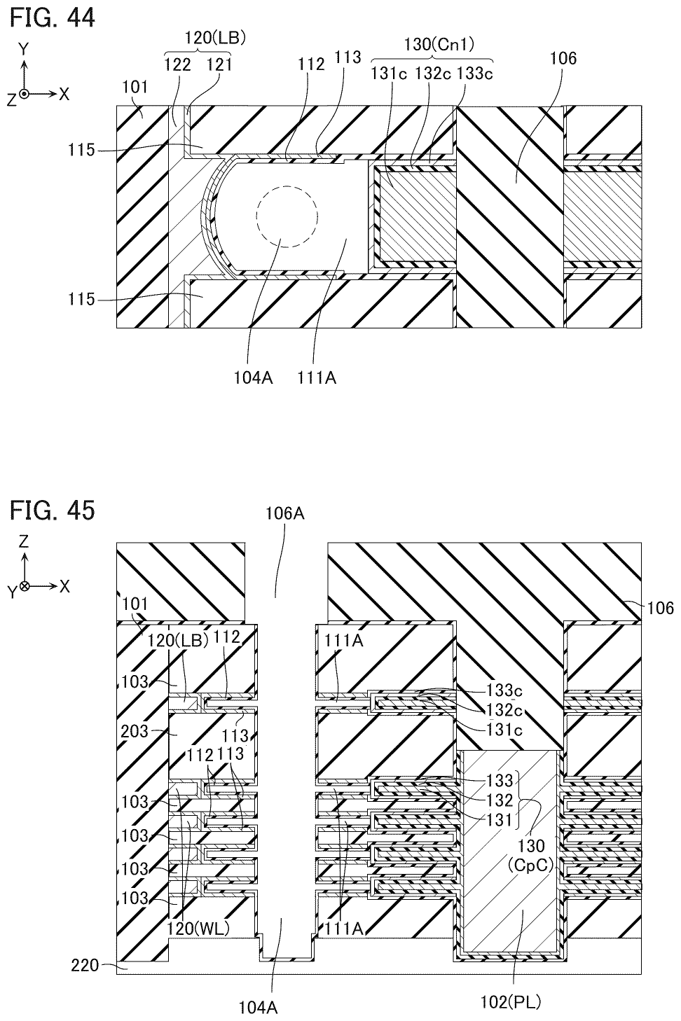

Next, as shown in FIGS. 44 and 45, for example, the insulating layer 106 is formed inside the opening 205A and on an upper surface of the structure shown in FIG. 43. Next, a portion located in an upper portion of the sacrifice layer 104Sc, of the insulating layer 106 is removed to form an opening 106A, and the sacrifice layers 104Sc, 111Sc removed via the opening 106A to form the openings 104A, 111A. This step is performed by the likes of CVD, RIE, and wet etching, for example.

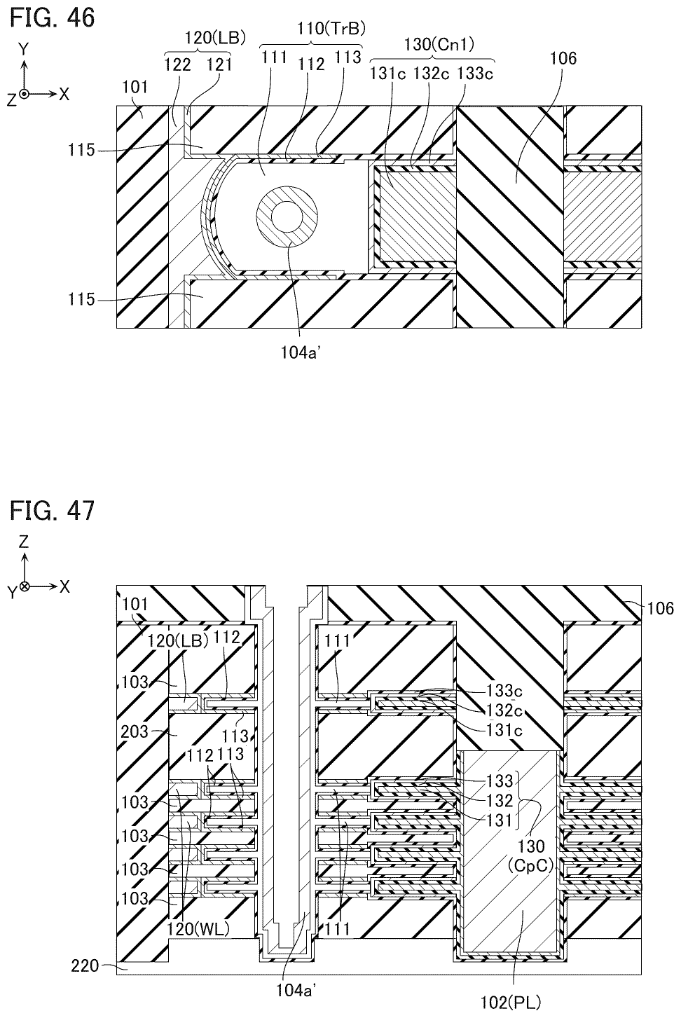

Next, as shown in FIGS. 46 and 47, for example, the semiconductor layer 111 is formed inside the openings 104A, 111A. The opening 111A is filled in by the semiconductor layer 111. On the other hand, the opening 104A is not filled in by the semiconductor layer 111. This step is performed by the likes of ALD (Atomic Layer Deposition), for example.

In addition, as shown in FIGS. 46 and 47, for example, a conductive oxide film 104a′ including a similar material to the conductive oxide film 104a is formed inside the opening 104A. In this step, the opening 104A is not filled in by the conductive oxide film 104a′. This step is performed by a method such as CVD, for example.

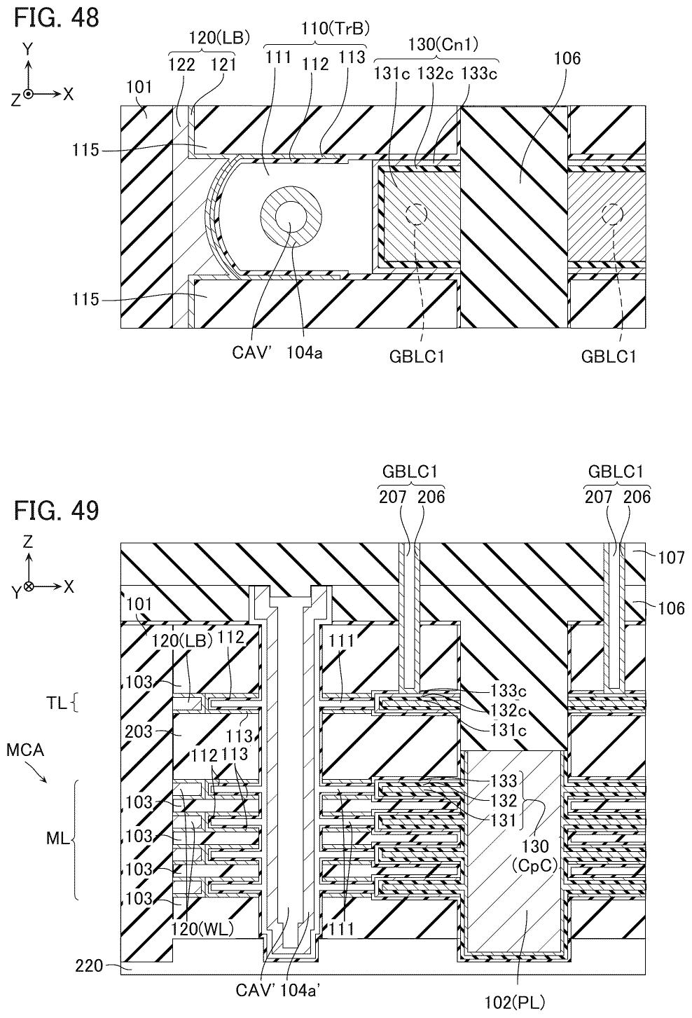

Next, as shown in FIGS. 48 and 49, for example, the insulating layer 107 of the likes of silicon oxide (SiO₂) is formed on an upper surface of the structure shown in FIG. 47, and an inner region CAV′ formed inside the via wiring 104. In addition, portions corresponding to the contact GBLC1 are removed from the insulating layer 106, insulating layer 107, and so on, to form an opening, and the conductive film 206 and the insulating film 207 formed in the opening. This step is performed by the likes of RIE, and the likes of CVD, for example.

Next, the wiring layer M0 including the global bit line GBL, the plurality of wirings m0, and so on, the wiring layer M1 including the plurality of wirings m1, and so on, and the plurality of first bonding electrodes P_{I1}, are formed on an upper surface of the structure shown in FIG. 49.

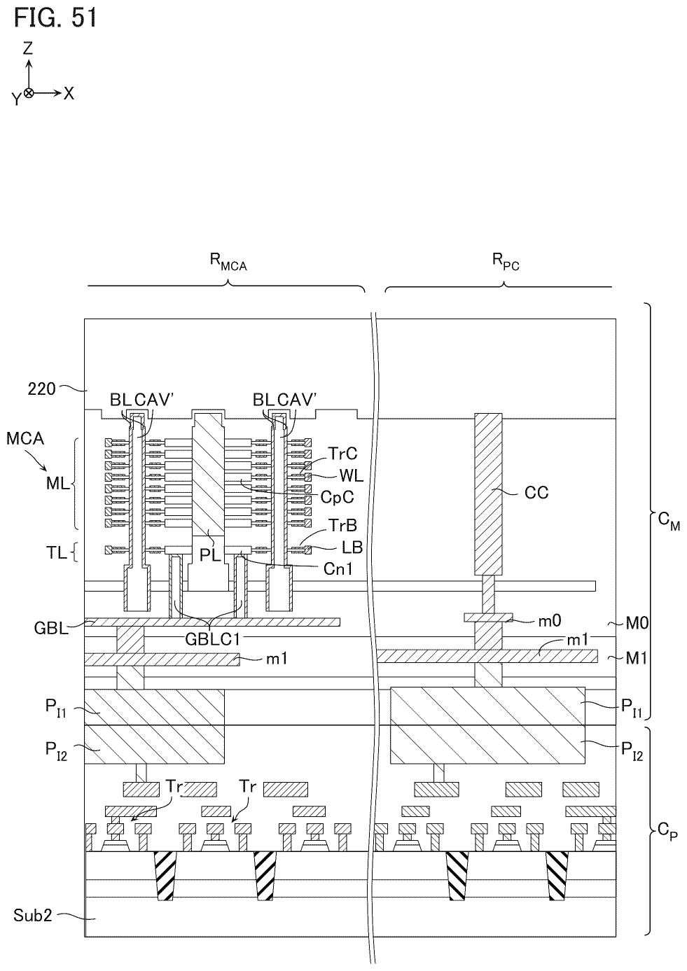

Next, as shown in FIGS. 50 and 51, a wafer including the chip C_{M} in which the memory cell array MCA has been formed by the above steps, is vertically inverted so that the substrate Sub will be upward and the global bit line GBL downward, and a front surface of the wafer including the chip C_{M} and a front surface of a wafer including the chip C_{P} are faced against each other (FIG. 50), and bonded via the first bonding electrode P_{I1} and the second bonding electrode P_{I2} (FIG. 51). Note that hydrogen (H), and so on, is sometimes generated in a formation step (FIG. 49) or bonding step (FIGS. 50 and 51) of these bonding electrodes.

Next, as shown in FIG. 51, the substrate Sub and the insulating layer 221 are removed. This step is performed by the likes of grinding, CMP (Chemical Mechanical Polishing), and wet etching, for example.

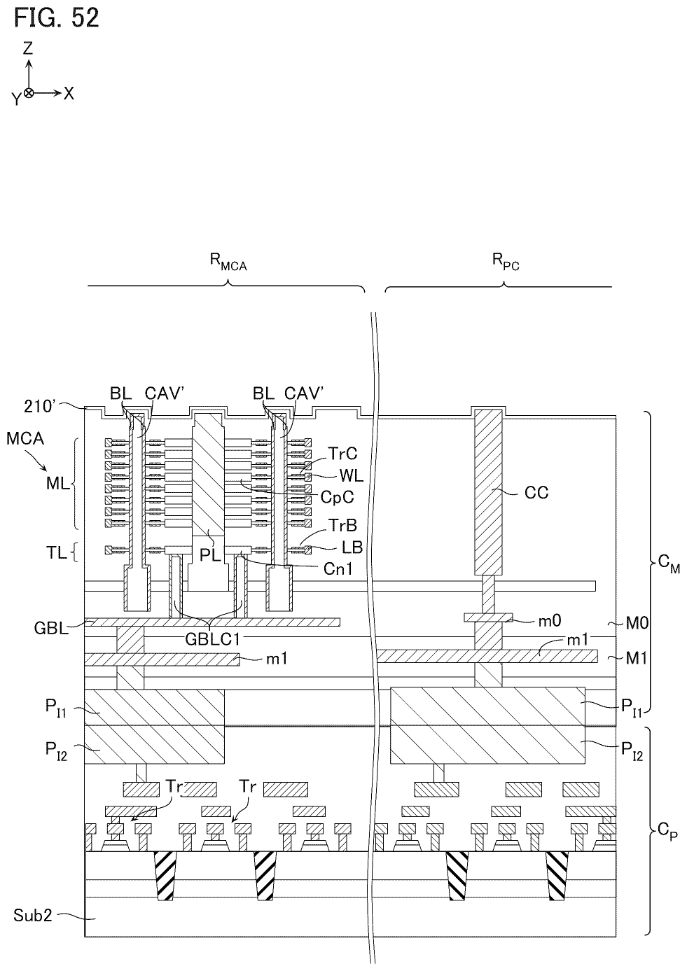

Next, as shown in FIG. 52, the semiconductor layer 220 is removed, and an insulating layer 210′ including a similar material to the insulating layer 210 formed on an upper surface of the structure. This step is performed by the likes of CVD, for example.

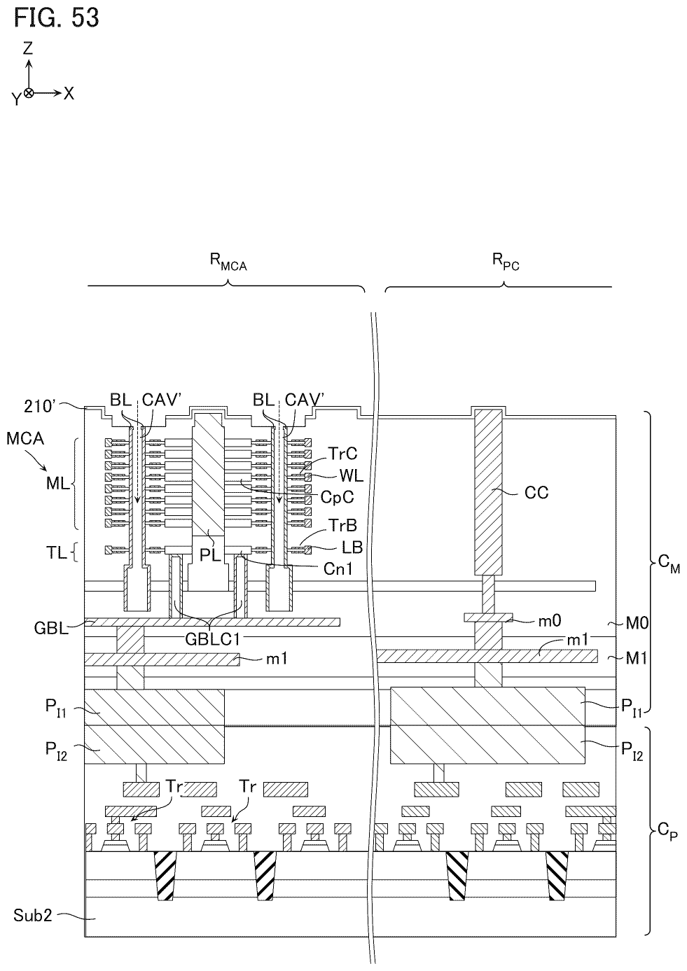

Next, as shown in FIG. 53, a part of the insulating layer 210′ above the bit line BL, and the upper end portion of the bit line BL, are removed, and an upper portion of the inner region CAV′ opened. This step is performed by the likes of RIE, for example.

Next, as shown in FIGS. 53 and 54, annealing under an oxygen (O₂) atmosphere is performed. In this step, a comparatively large amount of oxygen (O₂) diffuses into the inner region CAV′ via an opening of the inner region CAV′ upper portion. Hence, oxygen (O₂) diffuses into the plurality of semiconductor layers 111 arranged in the Z-direction, via the conductive oxide film 104a including an oxide material, and excessive oxygen deficiency present in the plurality of semiconductor layers 111 is restored. Note that in this step, as shown in FIG. 53, the plate line PL and the contact CC are covered by the insulating layer 210′, so their oxidation does not proceed.

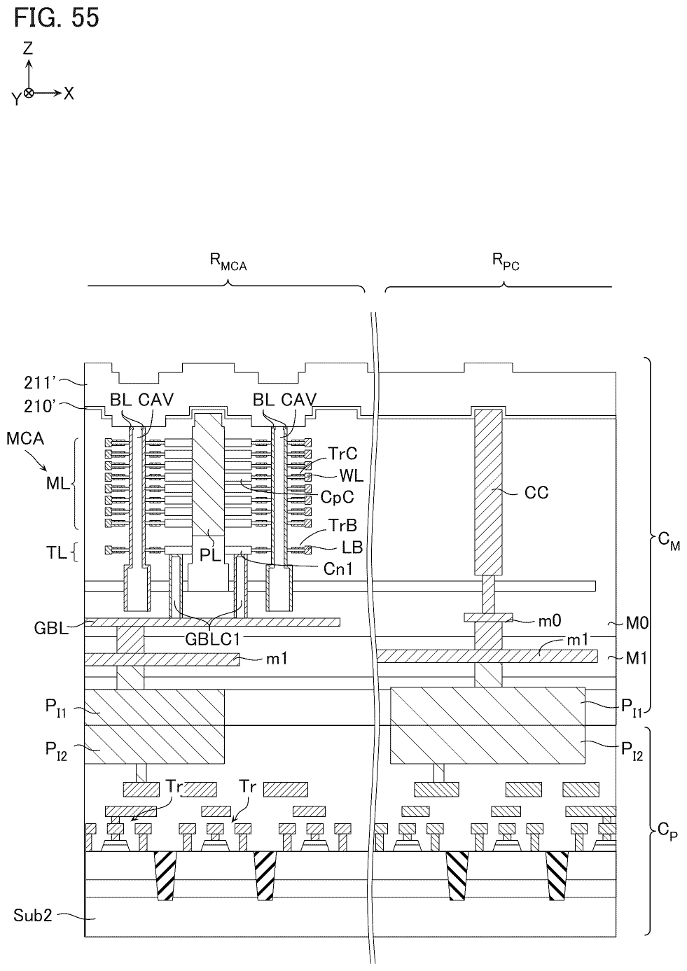

Next, as shown in FIG. 55, an insulating layer 211′ including a similar material to the insulating layer 211 is formed. This step is performed by the likes of CVD, for example.

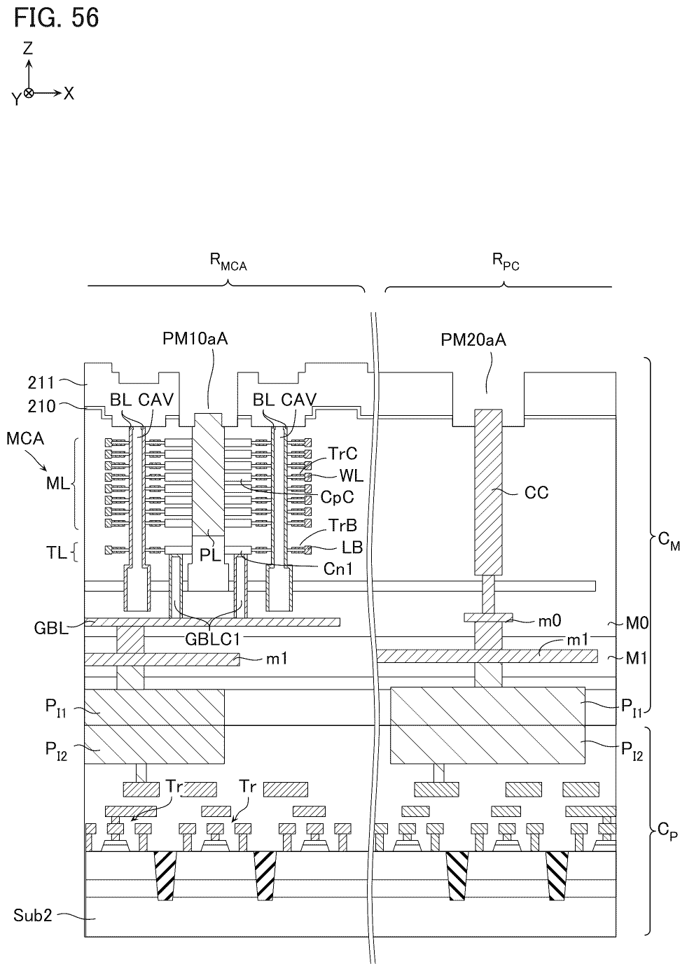

Next, as shown in FIG. 56, parts of the insulating layer 211′ and the insulating layer 210′ are removed, whereby the insulating layer 210 and the insulating layer 211, and an opening PM10aA and an opening PM20aA, are formed. An upper end portion of the plate line PL is exposed in the opening PM10aA. An upper end portion of the contact CC is exposed in the opening PM20aA. This step is performed by the likes of RIE, for example.

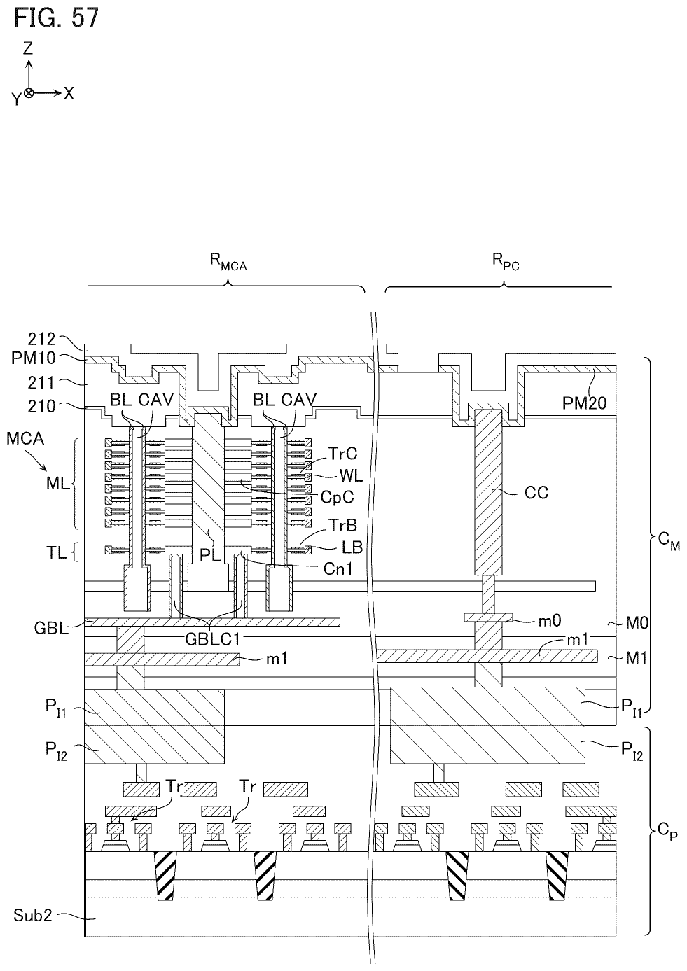

Next, as shown in FIG. 57, a similar material to the conductive layers PM10, PM20 and similar material to the insulating layer 212 are formed on an upper surface of the structure shown in FIG. 56, and patterning is performed by photolithography, and so on, and the conductive layers PM10, PM20, and the insulating layer 212 formed. This step is performed by the likes of CVD and wet etching, for example.

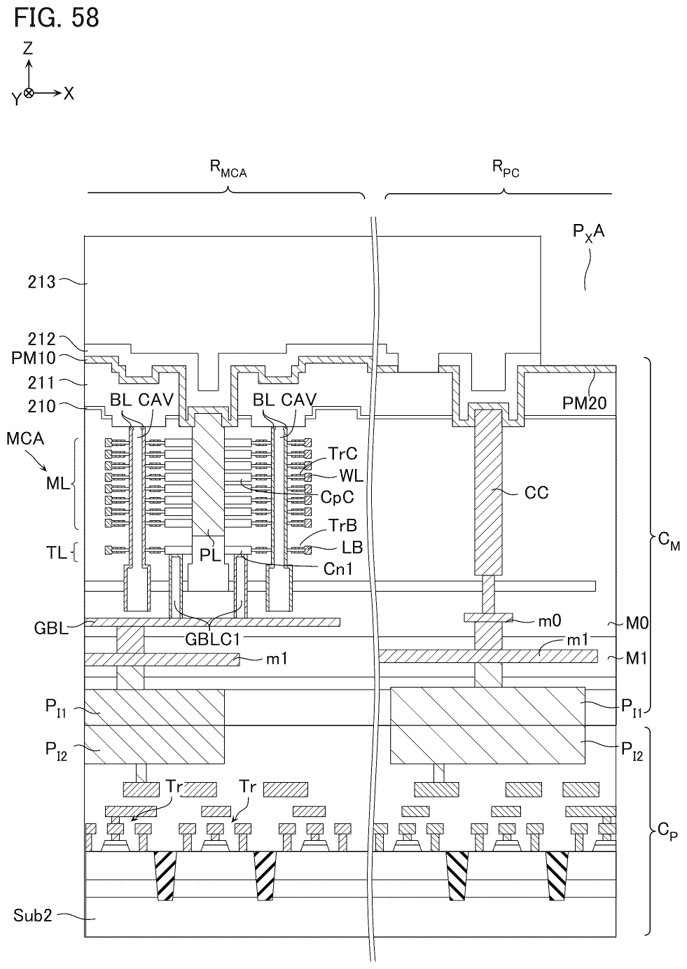

Next, as shown in FIG. 58, a similar material to the insulating layer 213 is formed on an upper surface of the structure shown in FIG. 57, and a portion corresponding to the external pad electrode P_{X} removed, whereby the insulating layer 213 and an opening P_{X}A are formed. A part of an upper surface of the conductive layer PM20 is exposed in the opening P_{X}A. This step is performed by the likes of CVD and RIE, for example.

Next, a similar material to the conductive layer MA10 and the conductive layer MA20 is formed on an upper surface of the structure shown in FIG. 58, and patterning is performed by photolithography, and so on, and the conductive layer MA10 and the conductive layer MA20 formed. This step is performed by the likes of CVD and wet etching, for example.

As a result, the structures described with reference to FIGS. 1 to 11 are formed.

### Advantages

Sometimes, a transistor having an oxide semiconductor as its channel will undergo an increase in oxygen deficiency in the oxide semiconductor (semiconductor layer 111), due to hydrogen (H), and so on, generated in a manufacturing step after transistor formation, and characteristics of the transistor will degrade.

Sometimes, the semiconductor memory device according to the present embodiment will undergo an increase in oxygen deficiency in the oxide semiconductor (semiconductor layer 111) included in the transistors TrC, TrB, due to hydrogen (H), and so on, generated in the formation step (FIG. 49) or bonding step (FIGS. 50 and 51) of the bonding electrodes, for example, after formation of the transistors TrC, TrB.

However, the semiconductor memory device according to the present embodiment comprises the inner region CAV. This makes it possible for there to be performed an oxygen annealing in which the semiconductor layers 111 stacked over several m from a position of the upper end of the via wiring 104 (bit line BL) (oxygen introduction portion) to a downward position, are all uniformly supplied with oxygen via the inner region CAV being a cavity, for example, after the bonding step, as shown in FIGS. 53 and 54. As a result, in the semiconductor memory device according to the present embodiment, characteristics of the transistors TrC, TrB stacked therein can be improved and homogenized.

Moreover, the semiconductor memory device according to the present embodiment comprises the conductive layer PM10 covering the upper end of the via wiring 104 (bit line BL) (FIG. 3). Due to the conductive layer PM10, hydrogen (H), and so on, can be prevented from diffusing into the transistors TrC, TrB from above the conductive layer PM10, after formation of the conductive layer PM10 (from FIG. 57 onwards). Hence, degradation of characteristics of the transistors TrC, TrB can be suppressed.

### Modified Example 1 of First Embodiment

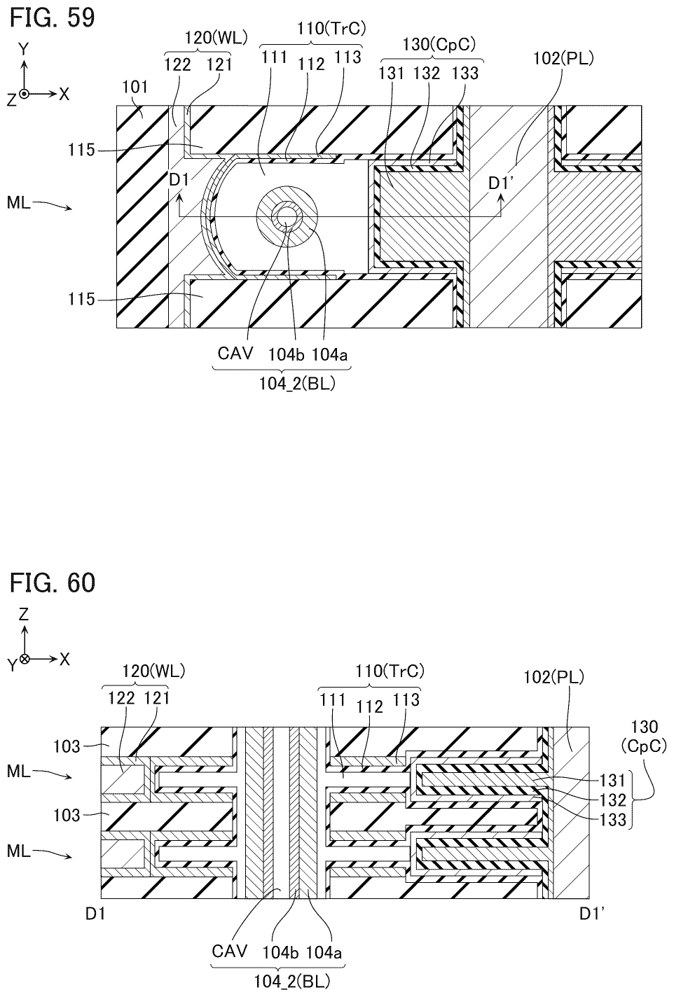

Next, modified example 1 of the semiconductor memory device according to the first embodiment will be described with reference to FIGS. 59 and 60. FIGS. 59 and 60 are schematic cross-sectional views showing a part of a configuration of a semiconductor memory device according to the present modified example. FIG. 60 shows a cross section of the structure shown in FIG. 59 taken along the line D1-D1′ and viewed along a direction of the arrows.

The semiconductor memory device according to the present modified example (FIGS. 59 and 60) is basically configured similarly to the semiconductor memory device according to the first embodiment (FIGS. 6 and 7).

However, the semiconductor memory device according to the present modified example is not provided with the via wiring 104, but provided with a via wiring 104_2 instead. The via wiring 104_2 is basically configured similarly to the via wiring 104 (FIGS. 6 and 7). However, the via wiring 104_2 comprises a conductive layer 104b between the conductive oxide film 104a and the inner region CAV, for example.

The conductive layer 104b comprises a substantially cylindrical shape extending in the Z-direction, for example. An outer peripheral surface of the conductive layer 104b contacts an inner peripheral surface of the conductive oxide film 104a. The conductive layer 104b includes a conductive oxide of lower resistance than the conductive oxide film 104a, of the likes of ruthenium oxide (RuO₂), for example.

Such a structure makes it possible to provide a semiconductor memory device of higher speed, in which resistance of the bit line BL has been further lowered.

### Modified Example 2 of First Embodiment

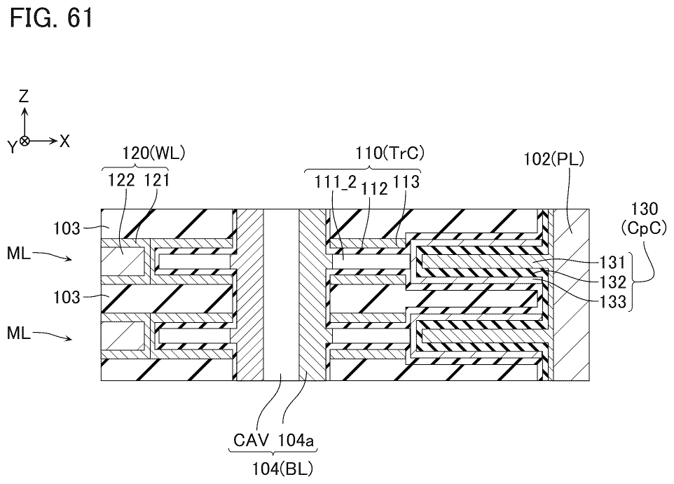

Next, modified example 2 of the semiconductor memory device according to the first embodiment will be described with reference to FIG. 61. FIG. 61 is a schematic cross-sectional view showing a part of a configuration of a semiconductor memory device according to the present modified example.

The semiconductor memory device according to the present modified example (FIG. 61) is basically configured similarly to the semiconductor memory device according to the first embodiment (FIG. 7). However, the semiconductor memory device according to the present modified example (FIG. 61) is not provided with the semiconductor layer 111, but provided with a semiconductor layer 111_2 instead.

The semiconductor layer 111_2 is basically configured similarly to the semiconductor layer 111 (FIG. 7). However, the semiconductor layer 111_2 is formed divided in the Z-direction every memory layer ML.

### Second Embodiment

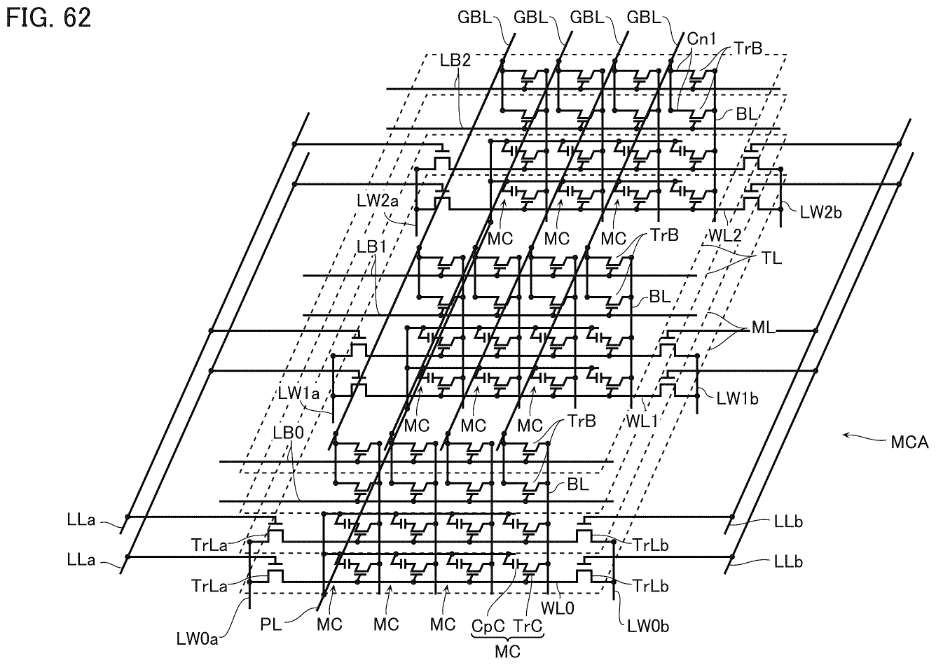

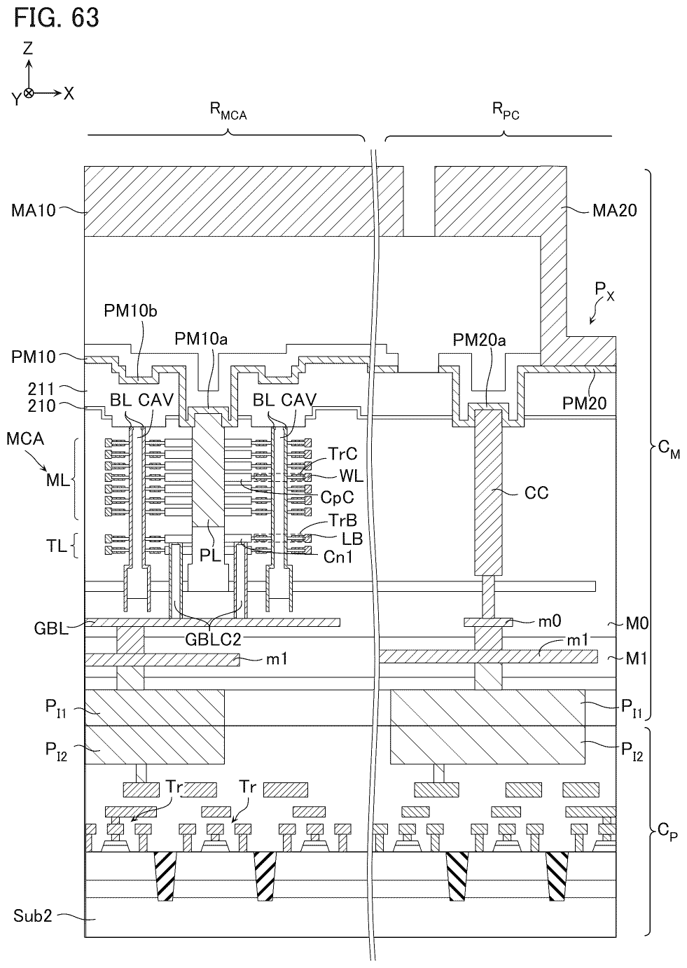

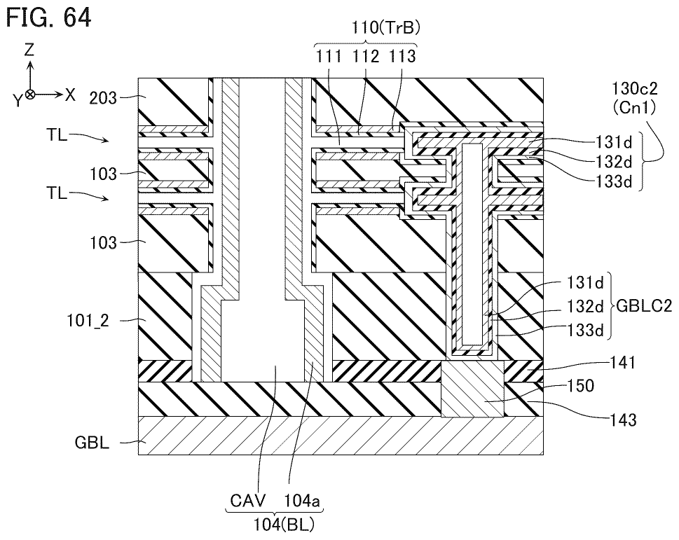

FIG. 62 is a schematic circuit diagram showing configurations of a semiconductor memory device according to a second embodiment. FIGS. 63 and 64 are schematic cross-sectional views showing a part of a configuration of the semiconductor memory device according to the present embodiment. In the following description, portions similar to in the first embodiment will be assigned with the same symbols as in the first embodiment, and descriptions thereof omitted.

The semiconductor memory device according to the second embodiment is basically configured similarly to the semiconductor memory device according to the first embodiment. However, the semiconductor memory device according to the second embodiment comprises a plurality of the transistor layers TL (FIGS. 62 to 64). Moreover, the semiconductor memory device according to the second embodiment comprises a contact GBLC2 and a plug 150 (FIG. 64) instead of the contact GBLC1 (FIG. 9), and, in addition, comprises as a structure for realizing the electrode Cn1 an electrode structure 130c2 (FIG. 64) instead of the electrode structure 130c (FIG. 9).

As shown in FIG. 62, for example, the other electrodes of those transistors TrB that each have one of their electrodes connected to the same bit line BL, of a plurality of the transistors TrB, are each connected to the same global bit line GBL, via electrodes Cn1. These plurality of transistors TrB are connected in parallel between the bit line BL and the global bit line GBL.

The contact GBLC2 (FIG. 64) extends in the Z-direction. An upper portion of the contact GBLC2 is connected to a plurality of the electrode structures 130c2 arranged in the Z-direction. The contact GBLC2 is connected at its lower surface to the plug 150. The contact GBLC2 functions as an electrode for connecting the plurality of transistors TrB to the global bit line GBL, via the electrodes Cn1, for example.

The electrode structure 130c2 and the contact GBLC2 include a conductive layer 131d, an insulating layer 132d, and a conductive layer 133d that are integrally formed.

The conductive layer 131d is integrally provided inside the electrode structure 130c2 and inside the contact GBLC2. The conductive layer 131d includes a similar material to the conductive layer 131c.

The insulating layer 132d is integrally provided inside the electrode structure 130c2 and inside the contact GBLC2. The insulating layer 132d covers an outer peripheral surface of the conductive layer 131d. The insulating layer 132d includes a similar material to the insulating layer 132c.

The conductive layer 133d is integrally provided inside the electrode structure 130c2 and inside the contact GBLC2. The conductive layer 133d covers an outer peripheral surface of the insulating layer 132d. The conductive layer 133d is connected to a side surface in the X-direction of the semiconductor layer 111 of each transistor layer TL, by the electrode structure 130c2 of each transistor layer TL. The conductive layer 133d is connected to the plug 150 by a lower surface portion of the contact GBLC2. The conductive layer 133d includes a similar material to the conductive layer 133c.

The plug 150 extends in the Z-direction penetrating an insulating layer 141 of the likes of silicon nitride (SiN) and an insulating layer 143 of the likes of silicon oxide (SiO₂), and is connected at its lower surface to the global bit line GBL, for example. The plug 50 may include a stacked structure of titanium nitride (TiN) and tungsten (W), for example.

### Method of Manufacturing

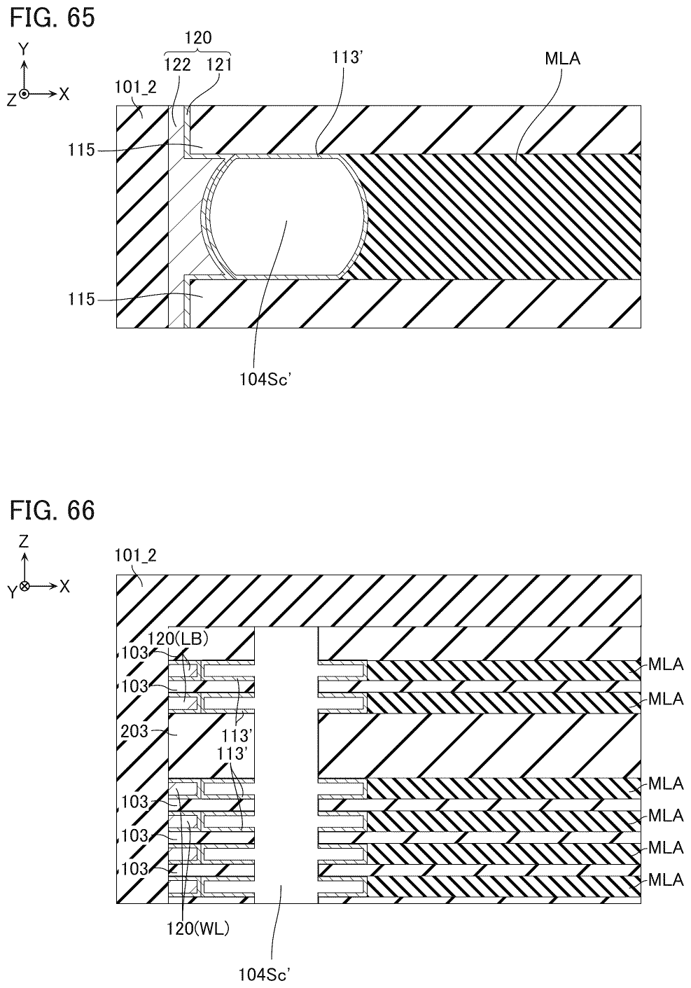

FIGS. 65 to 80 are schematic cross-sectional views for explaining a method of manufacturing the semiconductor memory device according to the second embodiment.

FIGS. 65, 67, 69, 71, and 73 show XY cross sections corresponding to the memory layer ML and transistor layer TL.

FIGS. 66, 68, 70, 72, and 74 to 80 show XZ cross sections corresponding to parts of the memory layers ML and transistor layers TL.

Note that in FIGS. 65 to 80 describing manufacturing of the chip C_{M}, an orientation representing upwards in processes of same method of manufacturing is depicted as a positive side in the Z-direction, and an orientation representing downwards in processes of same method of manufacturing is depicted as a negative side in the Z-direction. For example, in FIGS. 65 to 80, the front surface of the chip C_{M} is depicted on an upper side (a positive side in the Z-direction), and the back surface of the chip C_{M} is depicted on a lower side (a negative side in the Z-direction). In steps described with reference to FIG. 50 onwards, the front surface and the back surface of the chip C_{M} have their vertical positional relationship reversed, with the front surface of the chip C_{M} being depicted on a lower side (a negative side in the Z-direction), and the back surface of the chip C_{M} being depicted on an upper side (a positive side in the Z-direction). In FIGS. 65 to 80, positive and negative orientations in the Z-direction differ from in the configurations described with reference to FIGS. 63 and 64.

In same method of manufacturing, steps similar to the steps shown in FIGS. 12 to 21 are performed. However, unlike in FIGS. 12 to 21, there are a plurality of the sacrifice layers MLA formed above the insulating layer 203.

Next, as shown in FIGS. 65 and 66, for example, the conductive layer 120 is formed inside the opening 120A. This step is performed similarly to the step shown in FIGS. 22 and 23, for example. In addition, an insulating layer 101_2 of the likes of silicon oxide (SiO₂) is formed inside the opening 101A and on an upper surface of the structure shown in FIG. 21. This step is performed by a method such as CVD, for example.

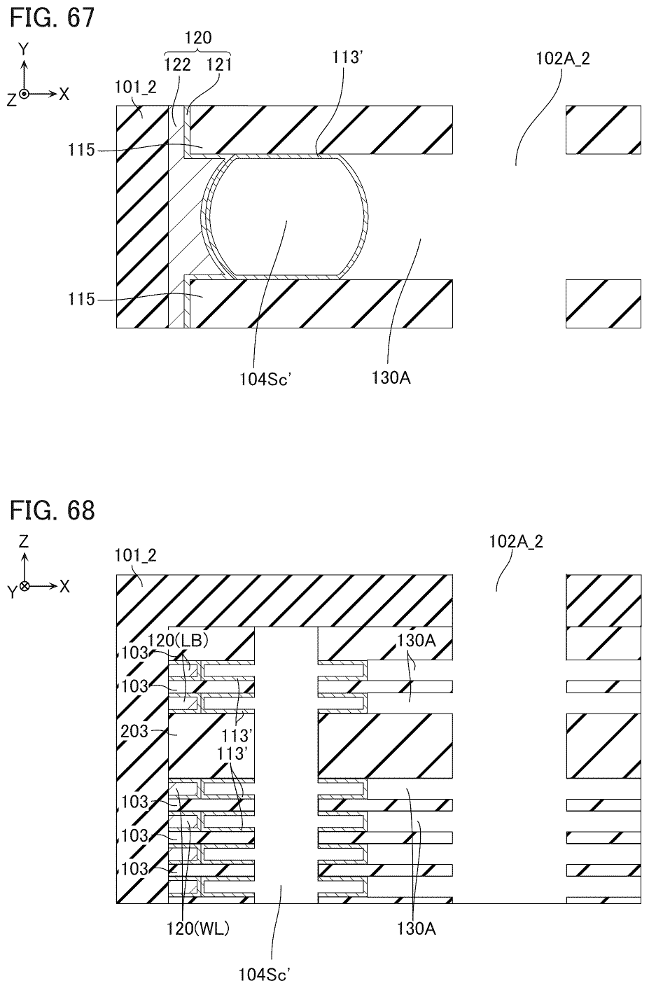

Next, as shown in FIGS. 67 and 68, for example, an opening 102A_2 is formed at a position corresponding to the conductive layer 102 and the insulating layer 106. The opening 102A_2 extends in the Z-direction, and penetrates the insulating layer 101_2, the plurality of insulating layers 103, insulating layer 203, and the plurality of sacrifice layers MLA that are stacked in the Z-direction. This step is performed by the likes of RIE, for example.

Next, as shown in FIGS. 67 and 68, for example, parts of the sacrifice layers MLA are selectively removed similarly to in the step shown in FIGS. 24 and 25, via the opening 102A_2, whereby the opening 130A is formed. This step is performed by the likes of wet etching, for example.

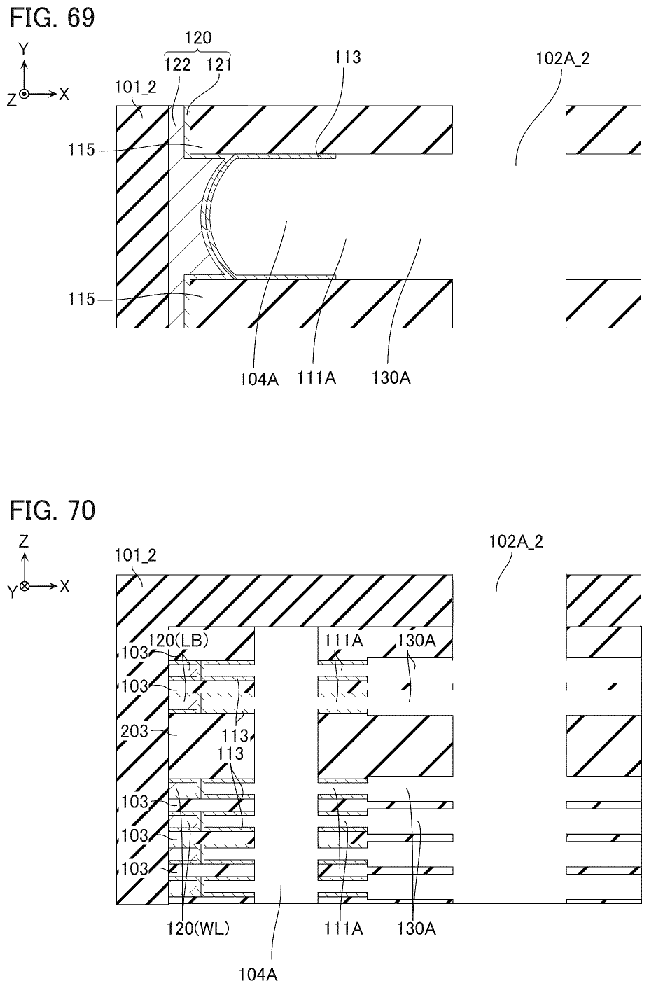

Next, as shown in FIGS. 69 and 70, for example, parts of the upper surfaces and parts of the lower surfaces of the insulating layers 103, 203, and a part of the side surface in the X-direction of the conductive layer 113′ that have been exposed in the opening 130A, are removed. This step causes width in the Z-direction of the opening 130A to increase. This step is performed by the likes of wet etching, for example. In addition, the sacrifice layer 104Sc′ is removed via the openings 102A_2, 130A, and the openings 104A, 111A formed. This step causes the openings 102A_2, 104A, 111A, 130A to communicate. This step is performed by the likes of wet etching, for example.

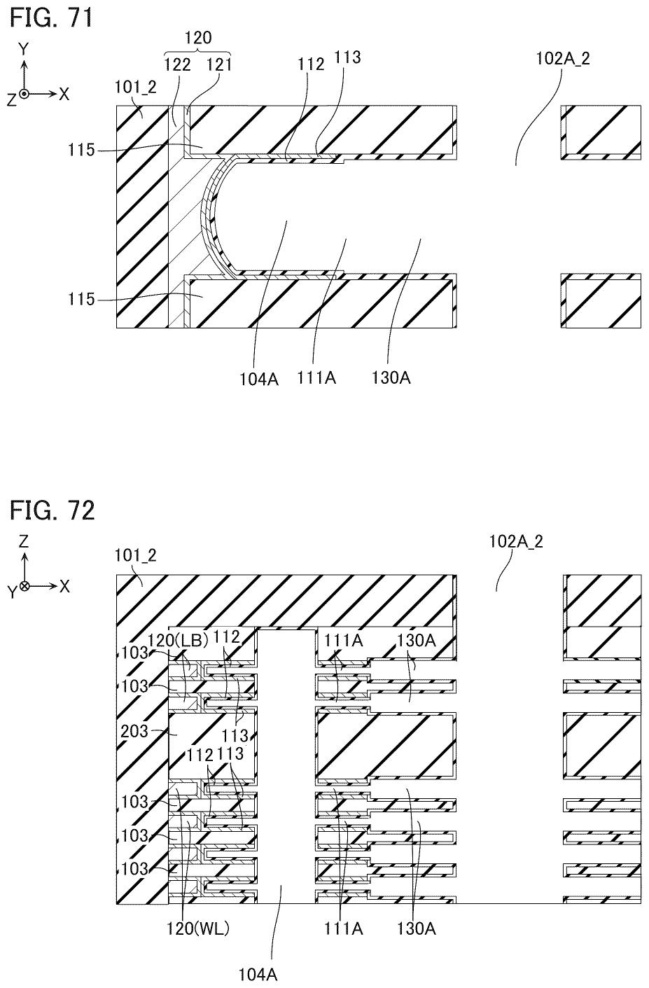

Next, as shown in FIGS. 71 and 72, for example, the insulating layer 112 is formed inside the openings 102A_2, 104A, 111A, 130A, via the opening 102A_2. This step is performed by the likes of CVD, for example.

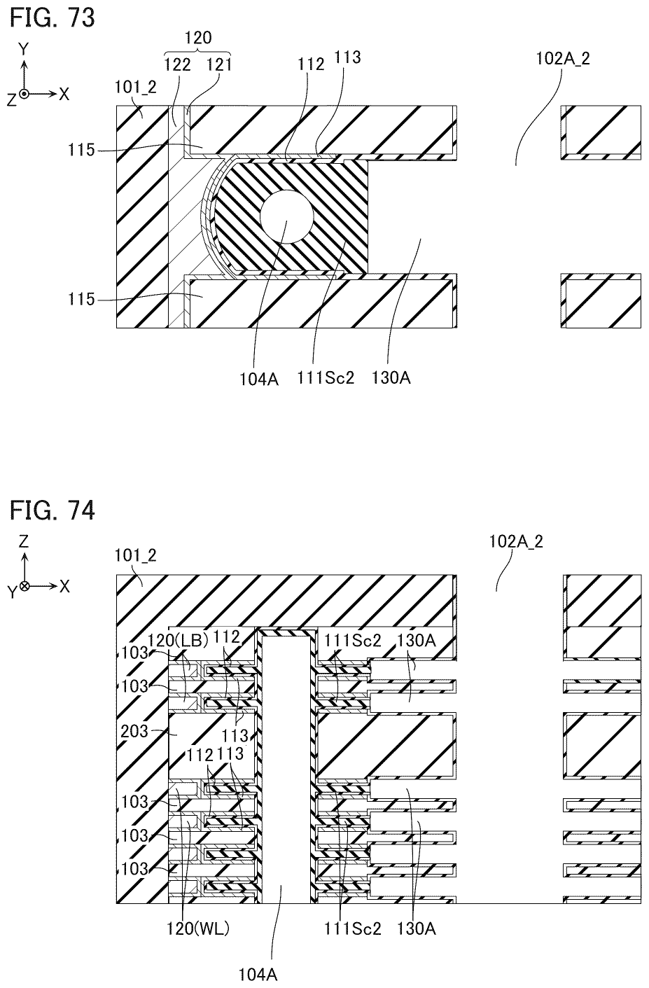

Next, as shown in FIGS. 73 and 74, for example, a sacrifice layer of the likes of silicon nitride (SiN) or titanium nitride (TiN) is formed inside the openings 102A_2, 104A, 111A, 130A, via the opening 102A_2, and parts of the sacrifice layer formed in the openings 102A_2, 130A removed via the opening 102A_2, and a sacrifice layer 111Sc2 formed. In this step, the opening 111A is filled in by the sacrifice layer 111Sc2, but the openings 102A_2, 104A, 130A are not filled in by the sacrifice layer 111Sc2. This step is performed by the likes of CVD, for example.

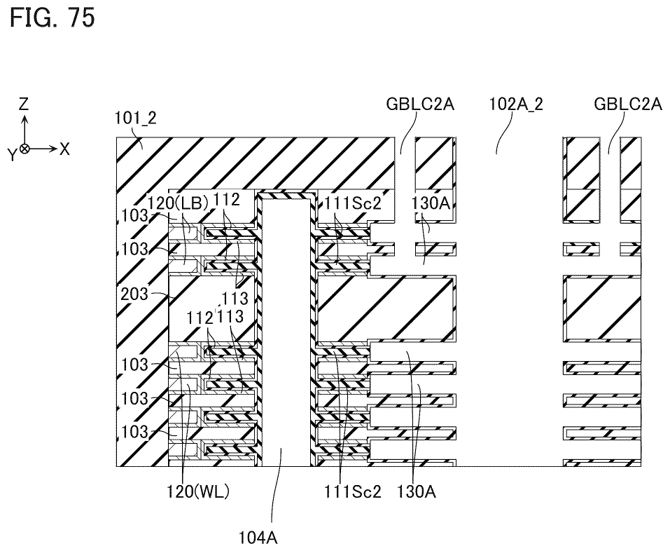

Next, as shown in FIG. 75, for example, an opening GBLC2A is formed at a position corresponding to the contact GBLC2. The opening GBLC2A extends in the Z-direction, and penetrates the insulating layer 101_2, and the plurality of insulating layers 103 above the insulating layer 203. This step causes the opening GBLC2A, and openings 130A above the insulating layer 203, to communicate. This step is performed by the likes of RIE, for example.

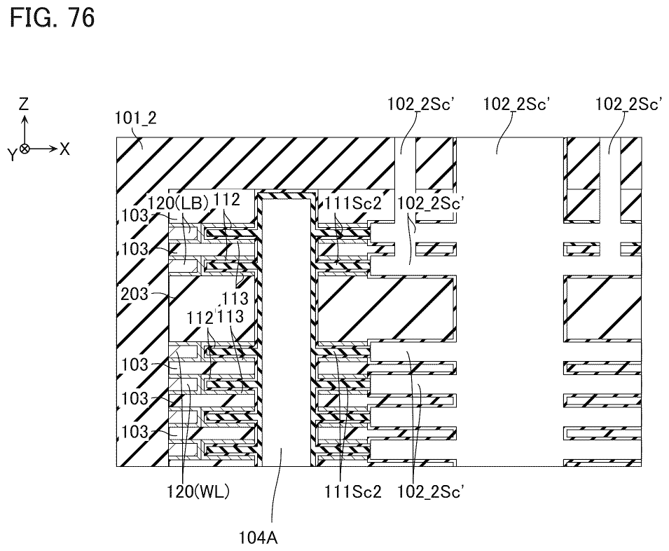

Next, as shown in FIG. 76, for example, a sacrifice layer 102_2Sc′ of the likes of silicon (Si) is formed inside the openings 102A_2, GBLC2A. This step is performed by the likes of CVD, for example.

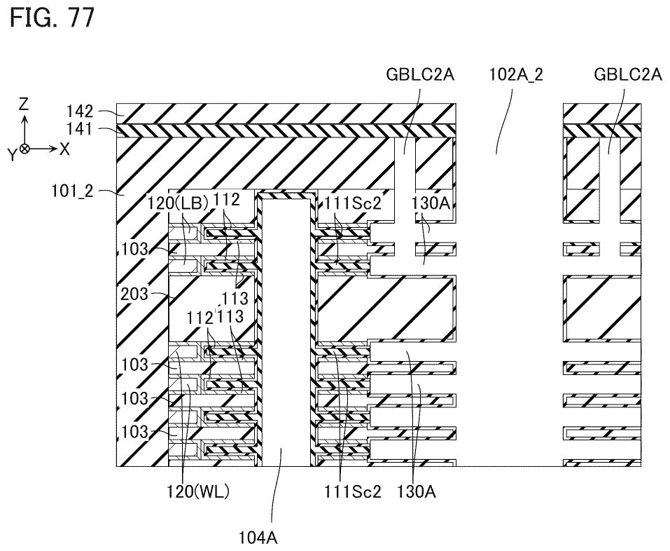

Next, as shown in FIG. 77, for example, films of similar materials to the insulating layer 141 and an insulating layer 142 are formed on upper surfaces of the insulating layer 101_2 and the sacrifice layer 102_2Sc′, and a portion corresponding to an upper portion of the conductive layer 102 removed, whereby the insulating layers 141, 142 are formed. In addition, the sacrifice layer 102_2Sc′ is removed, whereby the openings 102A_2, GBLC2A, 130A are formed. This step is performed by the likes of CVD, RIE, and wet etching, for example.

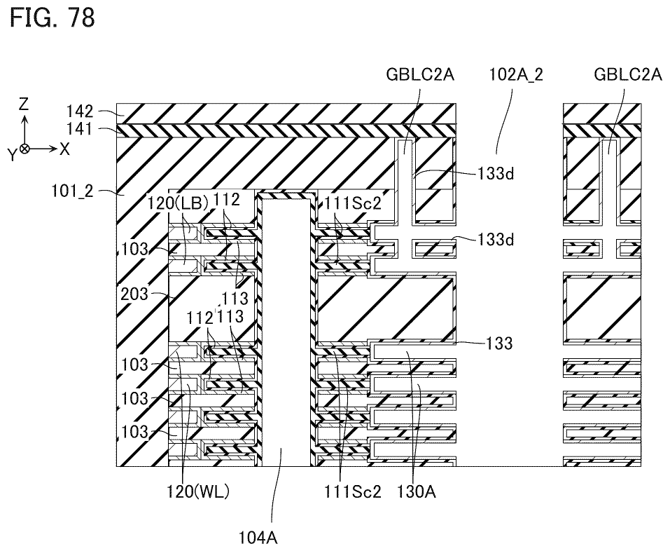

Next, as shown in FIG. 78, for example, the conductive layers 133, 133d are formed inside the openings 130A, GBLC2A. In this step, for example, a conductive oxide layer of the likes of indium tin oxide (ITO), for example, is formed inside the openings 102A_2, 130A, GBLC2A. Next, on the inside of the opening 102A_2, parts (portions formed on side surfaces of the insulating layers 103, 203) of the conductive oxide layer are removed, and the conductive oxide layer divided in the Z-direction, whereby the conductive layers 133, 133d are formed. This step is performed by the likes of CVD and RIE, for example.

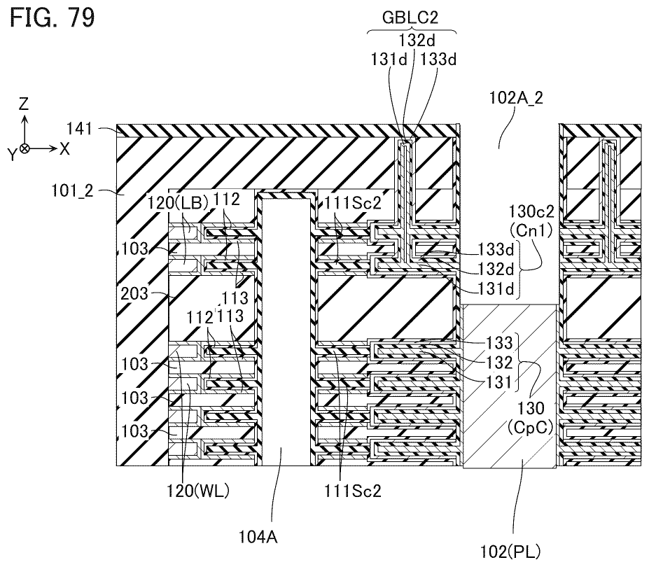

Next, as shown in FIG. 79, for example, the insulating layers 132, 132d, and the conductive layers 131, 131d are formed inside the openings 102A_2, 130A, GBLC2A, a similar material to the conductive layer 102 formed inside the opening 102A_2, and unrequired portions removed, whereby the capacitor structure 130, the electrode structure 130c2, the contact GBLC2, and the conductive layer 102(PL) are formed. This step is performed by the likes of CVD and RIE, for example.

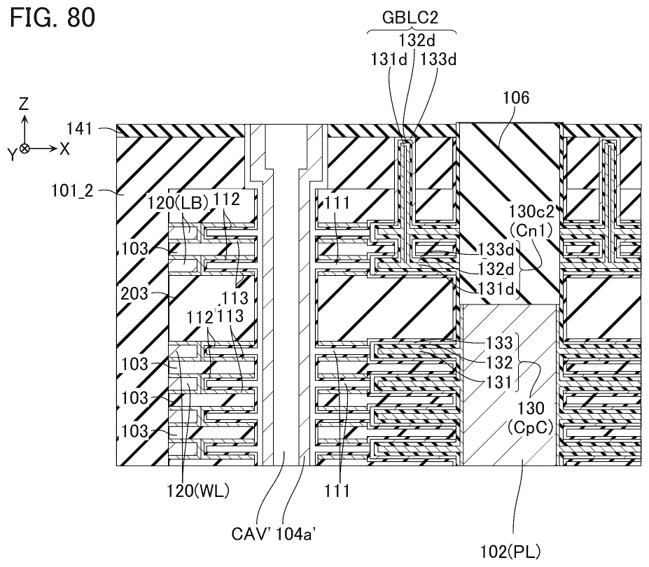

Next, as shown in FIG. 80, for example, the insulating layer 106 is formed in the opening 102A_2. Moreover, after portions above the opening 104A of the insulating layer 101_2 and the insulating layer 141 have been removed, and the sacrifice layer 111Sc2 removed via the opening 104A, the semiconductor layer 111 is formed. Moreover, the conductive oxide film 104a′ including a similar material to the conductive oxide film 104a, and the inner region CAV′, are formed inside the opening 104A. In this step, the opening 104A is not filled in by the conductive oxide film 104a′. This step is performed by methods such as CVD and CMP, for example.

Next, the insulating layer 143 (FIG. 64) is formed on an upper surface of the structure shown in FIG. 80, portions above the contact GBLC2 of the insulating layer 141 and the insulating layer 143 removed, and the plug 150 formed in the removed portions. Moreover, the wiring layer M0 including the global bit line GBL, the plurality of wirings m0, and so on, the wiring layer M1 including the plurality of wirings m1, and so on, and the plurality of first bonding electrodes P_{I1}, are formed above the insulating layer 143 and the plug 150.

Next, for example, steps similar to the steps described with reference to FIGS. 50 to 58 are performed, and the structures described with reference to FIGS. 63 and 64 formed.

### Advantages

In the present embodiment, the contact GBLC2 and the plurality of electrode structures 130c2 are configured by an integrated film structure, so that manufacturing of the contact GBLC2 and the plurality of electrode structures 130c2 can be efficiently performed, and a contribution made to reducing manufacturing costs of the semiconductor memory device. Moreover, the present embodiment makes it possible to provide a semiconductor memory device of high speed, in which the contact GBLC2 and the plurality of electrode structures 130c2 are connected with low resistance.

### Modified Example of Second Embodiment

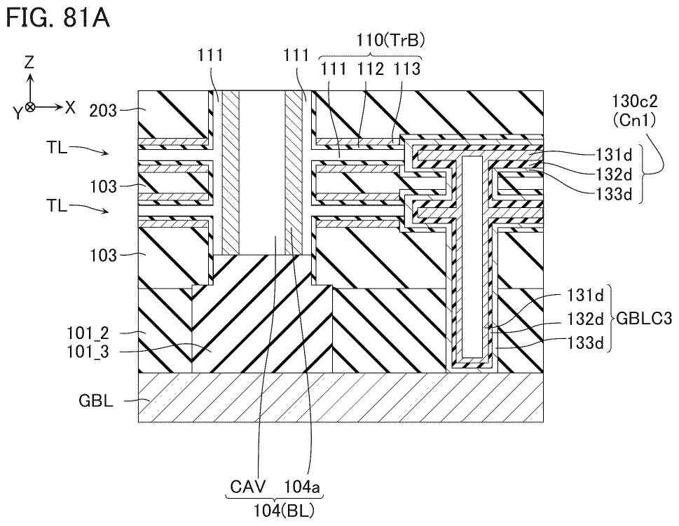

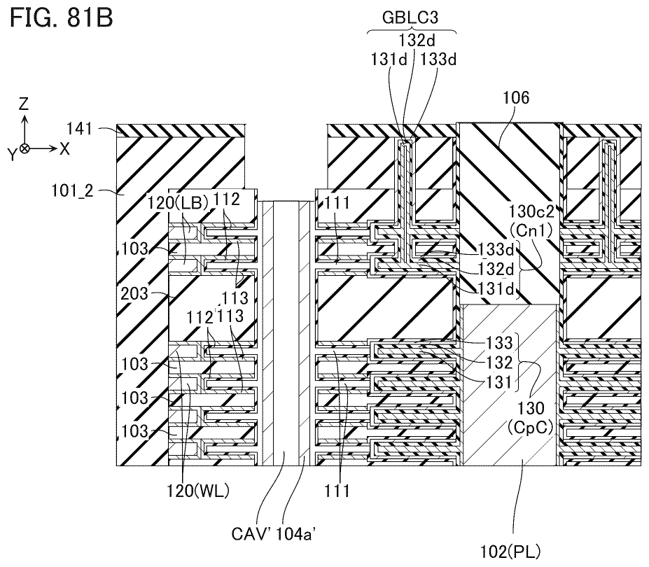

Next, a modified example of the semiconductor memory device according to the second embodiment will be described with reference to FIG. 81A. FIG. 81A is a schematic cross-sectional view showing a part of a configuration of a semiconductor memory device according to the present modified example.

The semiconductor memory device according to the present modified example (FIG. 81A) is basically configured similarly to the semiconductor memory device according to the second embodiment (FIG. 64). However, the semiconductor memory device according to the present modified example comprises a contact GBLC3 instead of the contact GBLC2, and, moreover, is not provided with the plug 150. Moreover, in the semiconductor memory device according to the present modified example, portions on a global bit line GBL side of the transistor layers TL, of the semiconductor layer 111 and the conductive oxide film 104a are removed, and the removed portions provided with an insulating layer 101_3 of the likes of silicon oxide (SiO₂).

The contact GBLC3 (FIG. 81A) is basically configured similarly to the contact GBLC2 (FIG. 64). However, the conductive layer 133d included in the contact GBLC3 has its lower surface connected directly to the global bit line GBL.

### Method of Manufacturing

FIG. 81B is a schematic cross-sectional view for explaining a method of manufacturing the semiconductor memory device according to the present modified example.

The semiconductor memory device according to the present modified example (FIG. 81A) is basically manufactured similarly to the semiconductor memory device according to the second embodiment. However, in manufacturing of the semiconductor memory device according to the present modified example, following a step corresponding to FIG. 80, as shown in FIG. 81B, the portions on the global bit line GBL side of the transistor layers TL, of the semiconductor layer 111 and the conductive oxide film 104a′ are removed. This step is performed by the likes of RIE, for example.

Next, the insulating layer 101_3 is formed by the likes of CVD in the portions removed in the step shown in FIG. 81B. Moreover, parts of the insulating layer 141 and the insulating layers 101_3, 106 on an upper surface of the structure shown in FIG. 81B are removed, and the conductive layer 133d included in the contact BGLC3 exposed, after which the wiring layer M0 including the global bit line GBL, the plurality of wirings m0, and so on, the wiring layer M1 including the plurality of wirings m1, and so on, and the plurality of first bonding electrodes P_{I1}, are formed.

Next, for example, steps similar to the steps described with reference to FIGS. 50 to 58 are performed, and the structure described with reference to FIG. 81A formed.

### Third Embodiment

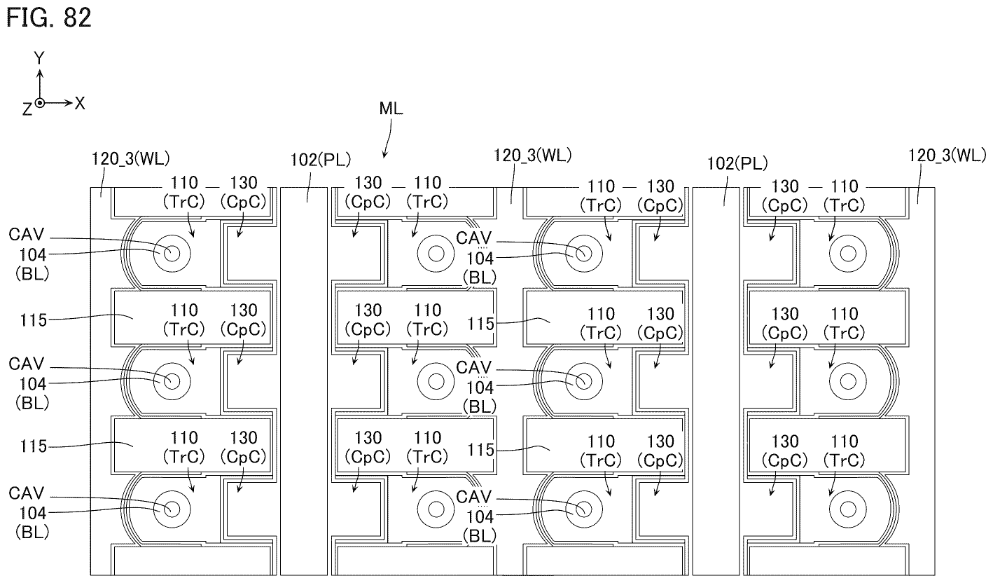

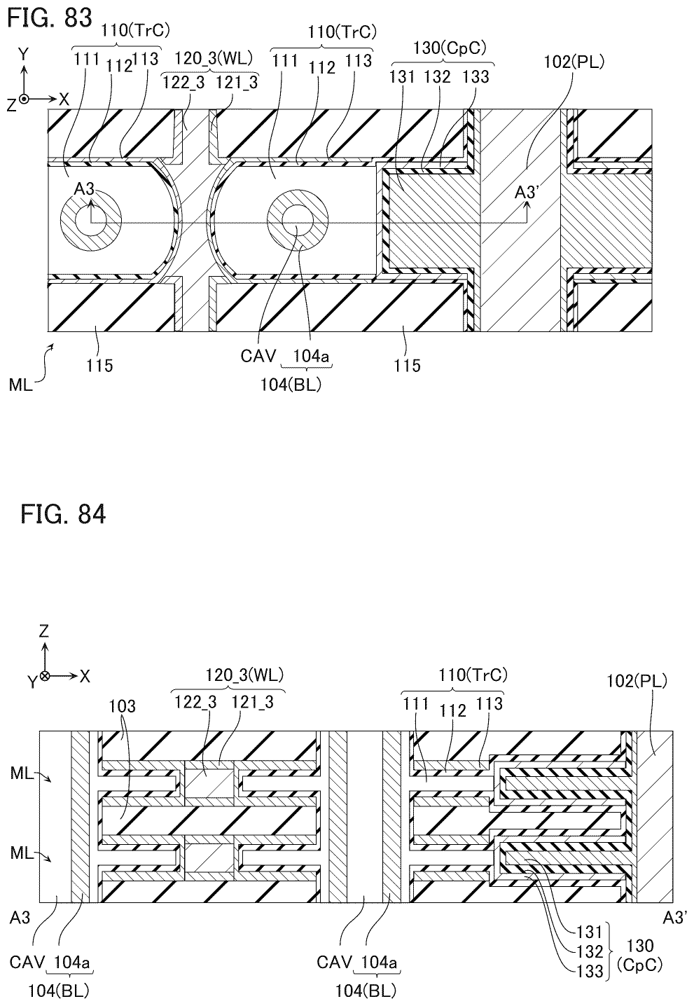

FIGS. 82 to 84 are schematic cross-sectional views showing a part of a configuration of a semiconductor memory device according to a third embodiment. FIG. 82 is a schematic cross-sectional view showing a part of a configuration of a memory layer ML. FIG. 83, which is a schematic cross-sectional view showing a part of a configuration of the memory layer ML, shows an enlarged part of FIG. 82. FIG. 84 shows a cross section of the structure shown in FIG. 83 taken along the line A3-A3′ and viewed along a direction of the arrows. In the following description, portions similar to in the first embodiment will be assigned with the same symbols as in the first embodiment, and descriptions thereof omitted.

The semiconductor memory device according to the third embodiment is basically configured similarly to the semiconductor memory device according to the first embodiment. However, the semiconductor memory device according to the third embodiment is not provided with the conductive layer 120 and the insulating layer 101 (FIG. 5), but comprises a conductive layer 120_3 (FIG. 82) instead.

The conductive layer 120_3 (FIGS. 83 and 84) is basically configured similarly to the conductive layer 120 (FIGS. 6 and 7). However, as shown in FIG. 83, for example, in the memory layer ML, the conductive layer 120_3 functions as the word line WL (FIG. 2) corresponding to the transistors TrC provided on both sides in the X-direction with respect to the conductive layer 120_3. In the transistor layer TL, for example, the conductive layer 120_3 functions as the bit line select line LB (FIG. 2) corresponding to the transistors TrB provided on both sides in the X-direction with respect to the conductive layer 120_3. The conductive layer 120_3 is connected at its side surfaces on both sides in the X-direction to the conductive layers 113 provided on both sides of it in the X-direction. The conductive layer 120_3 comprises a barrier conductive film 121_3 of the likes of titanium nitride (TiN) and a conductive film 122_3 of the likes of tungsten (W), for example.

The barrier conductive film 121_3 (FIG. 84) is basically configured similarly to the barrier conductive film 121 (FIG. 7). However, the barrier conductive film 121_3, unlike the barrier conductive film 121, is not provided on a side surface on one side in the X-direction (a side surface on a conductive layer 120_3 side) of the conductive layer 113.

### Method of Manufacturing

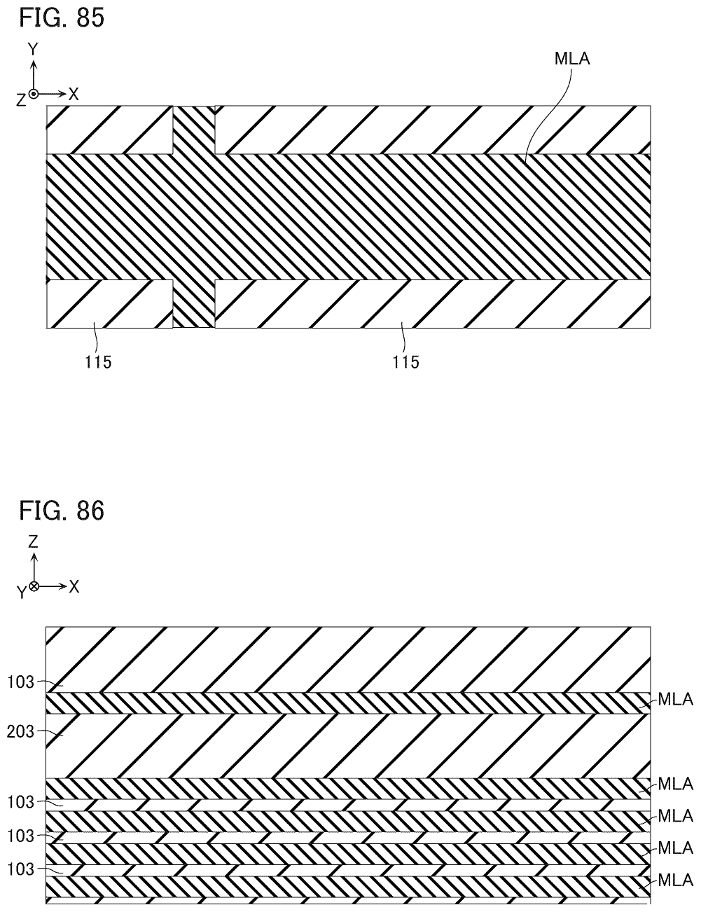

FIGS. 85 to 104 are schematic cross-sectional views for explaining a method of manufacturing the semiconductor memory device according to the third embodiment.

FIGS. 85, 87, 89, 91, 93, 95, 97, 99, 101, and 103 show XY cross sections corresponding to FIG. 83.

FIGS. 86, 88, 90, 92, 94, 96, 98, 100, 102, and 104 show XZ cross sections corresponding to parts of the memory layers ML and the transistor layer TL.

Note that in FIGS. 85 to 104, an orientation representing upwards in processes of same method of manufacturing is depicted as a positive side in the Z-direction, and an orientation representing downwards in processes of same method of manufacturing is depicted as a negative side in the Z-direction.

In same method of manufacturing, as shown in FIGS. 85 and 86, for example, the plurality of insulating layers 103 and the insulating layer 203, and the plurality of sacrifice layers MLA, are alternately formed above the unillustrated substrate Sub. This step is performed by the likes of CVD, for example.

Next, as shown in FIGS. 85 and 86, for example, the insulating layer 115 is formed. In this step, for example, an opening is formed at a position corresponding to the insulating layer 115. This opening extends in the Z-direction, and penetrates the plurality of insulating layers 103, insulating layer 203, and the plurality of sacrifice layers MLA that have been stacked in the Z-direction. This step is performed by the likes of RIE, for example. After formation of the opening, the insulating layer 115 is formed. This step is performed by the likes of CVD, for example.

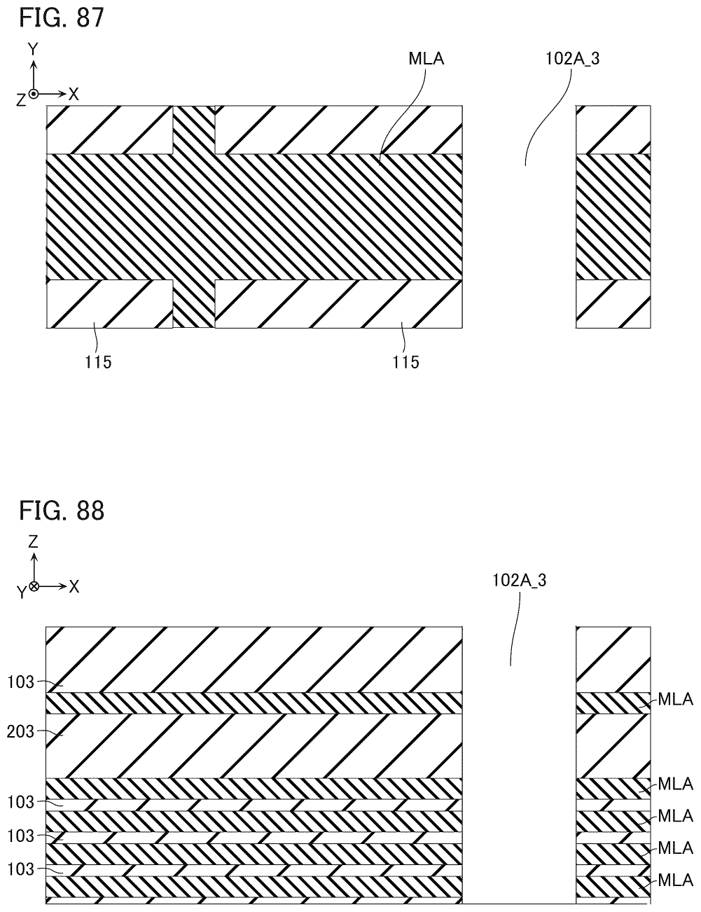

Next, as shown in FIGS. 87 and 88, for example, an opening 102A_3 is formed at a position corresponding to the conductive layer 102 and the insulating layer 106. The opening 102A_3 extends in the Z-direction, and penetrates the plurality of insulating layers 103, insulating layer 203, and the plurality of sacrifice layers MLA that have been stacked in the Z-direction. This step is performed by the likes of RIE, for example.

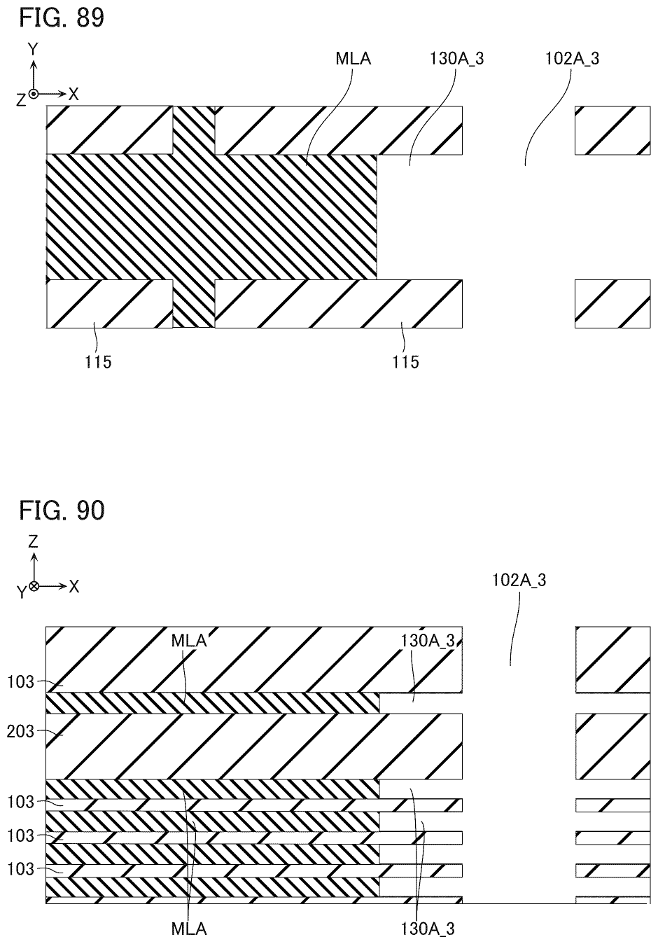

Next, as shown in FIGS. 89 and 90, for example, an opening 130A_3 is formed via the opening 102A_3. Parts of the upper surfaces and parts of the lower surfaces of the insulating layers 103, 203 are exposed in the opening 130A_3. In this step, for example, parts of the sacrifice layer MLA are selectively removed via the opening 102A_3. This step is performed by the likes of wet etching, for example.

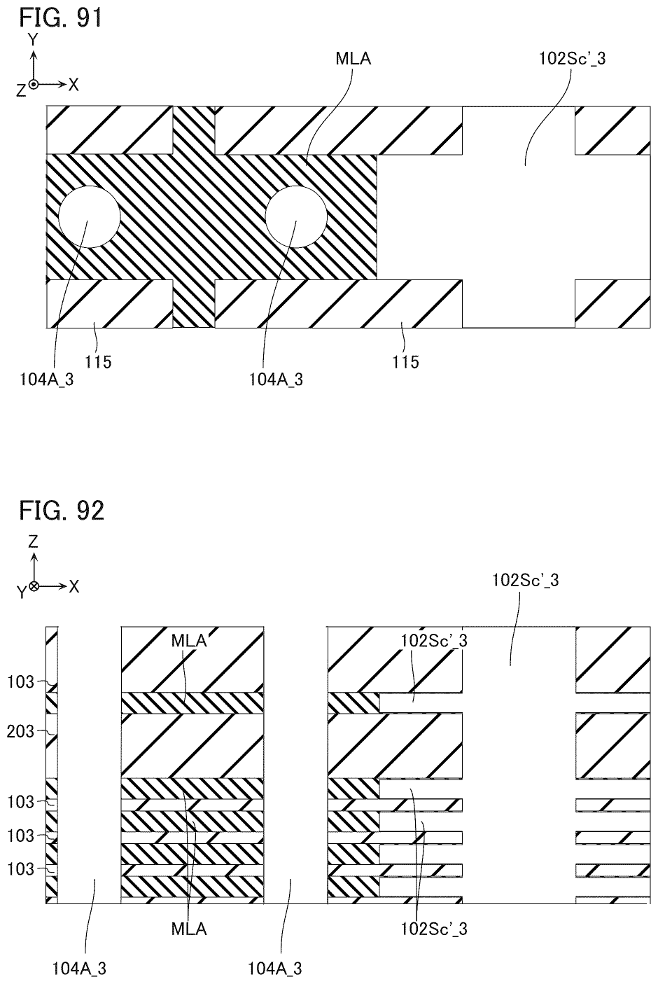

Next, as shown in FIGS. 91 and 92, for example, silicon (Si) or the like is filled in to insides of the openings 102A_3, 130A_3, and a sacrifice layer 102Sc′_3 formed. This step is performed by the likes of CVD, for example.

Next, as shown in FIGS. 91 and 92, for example, an opening 104A_3 is formed. The opening 104A_3 extends in the Z-direction, and penetrates the plurality of insulating layers 103, insulating layer 203, and the plurality of sacrifice layers MLA that have been stacked in the Z-direction. This step is performed by the likes of RIE, for example.

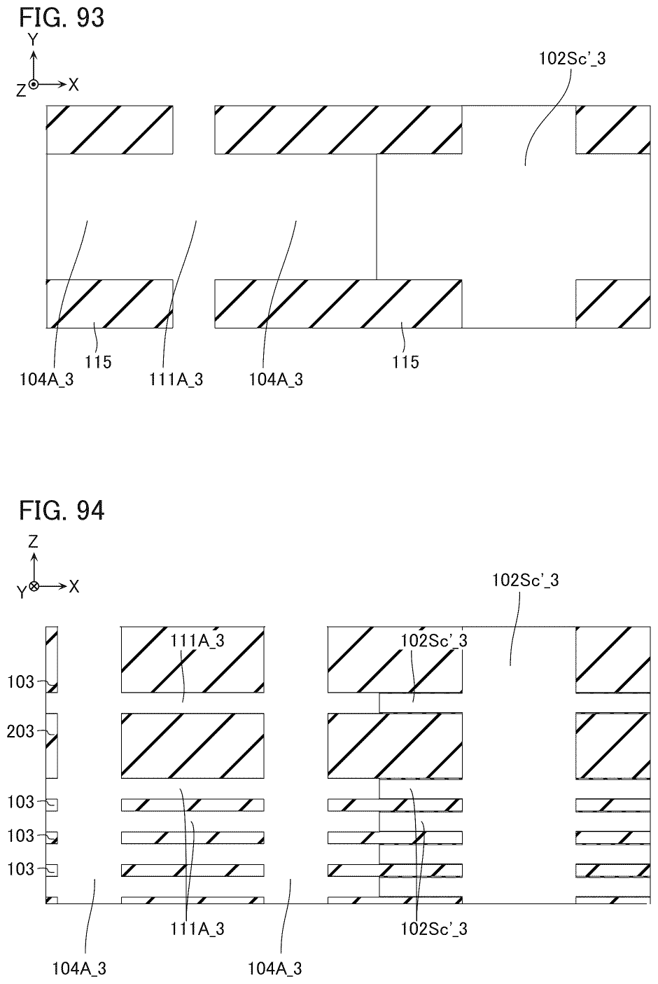

Next, as shown in FIGS. 93 and 94, for example, the sacrifice layer MLA is selectively removed, and an opening 111A_3 formed, via the opening 104A_3. This step is performed by the likes of wet etching, for example.

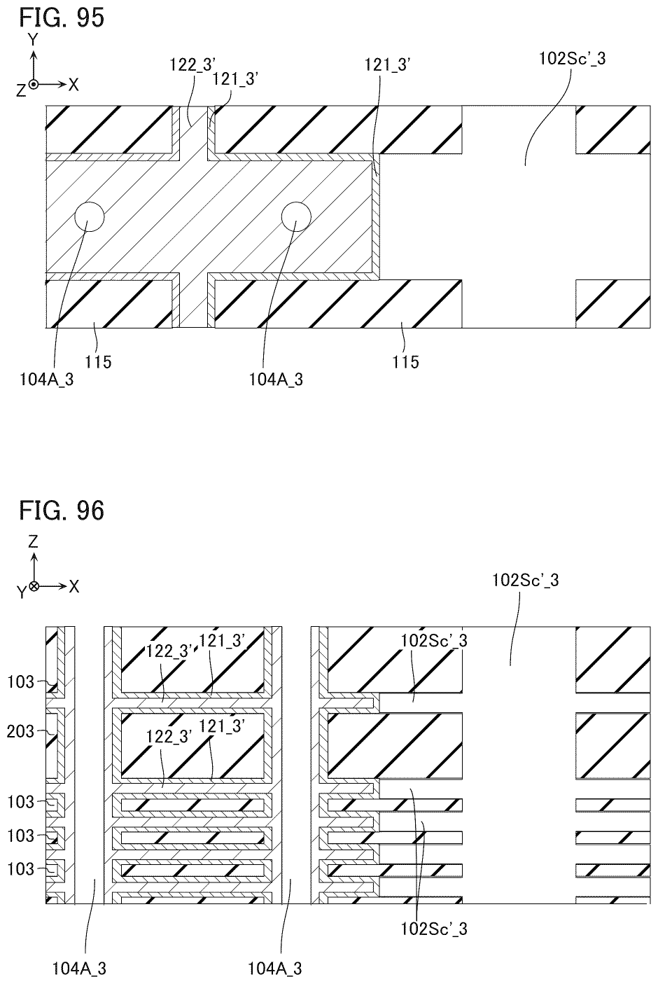

Next, as shown in FIGS. 95 and 96, for example, a barrier conductive film 121_3′ including a similar material to the barrier conductive film 121_3, and the conductive film 122_3′ including a similar material to the conductive film 122_3, are formed inside the openings 111A_3, 104A_3, via the opening 104A_3. In this step, the opening 111A_3 is filled in by the barrier conductive film 121_3′ and the conductive film 122_3′, but the opening 104A_3 is not filled in by the barrier conductive film 121_3′ and the conductive film 122_3′. This step is performed by the likes of CVD, for example.

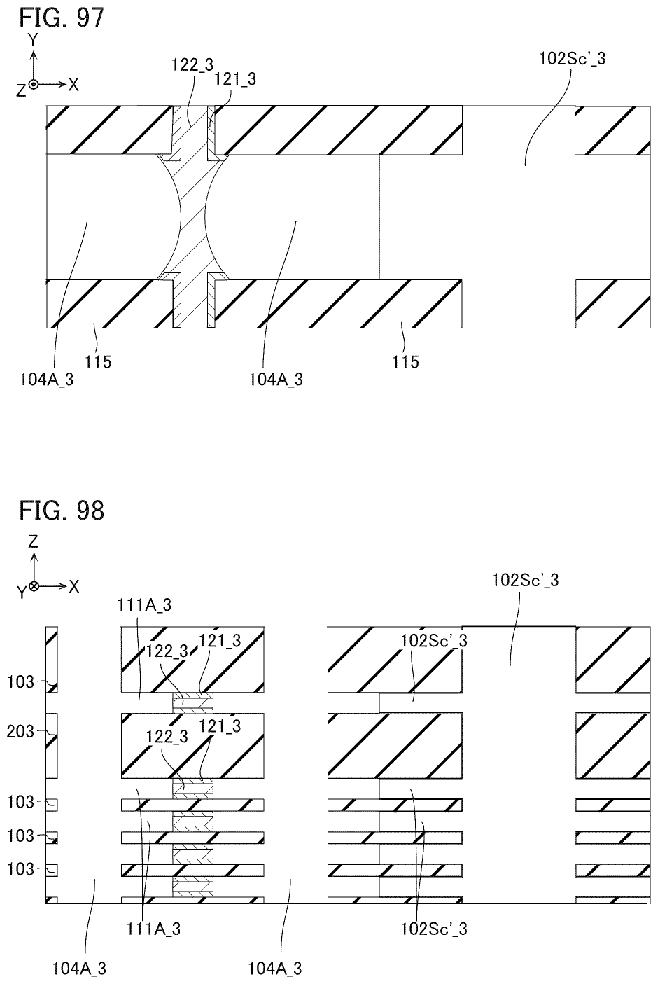

Next, as shown in FIGS. 97 and 98, for example, parts of the barrier conductive film 121_3′ and the conductive film 122_3′ are removed, and the barrier conductive film 121_3 and the conductive film 122_3 formed in a part of the inside of the opening 111A_3, via the opening 104A_3. This step is performed by the likes of CVD, for example.

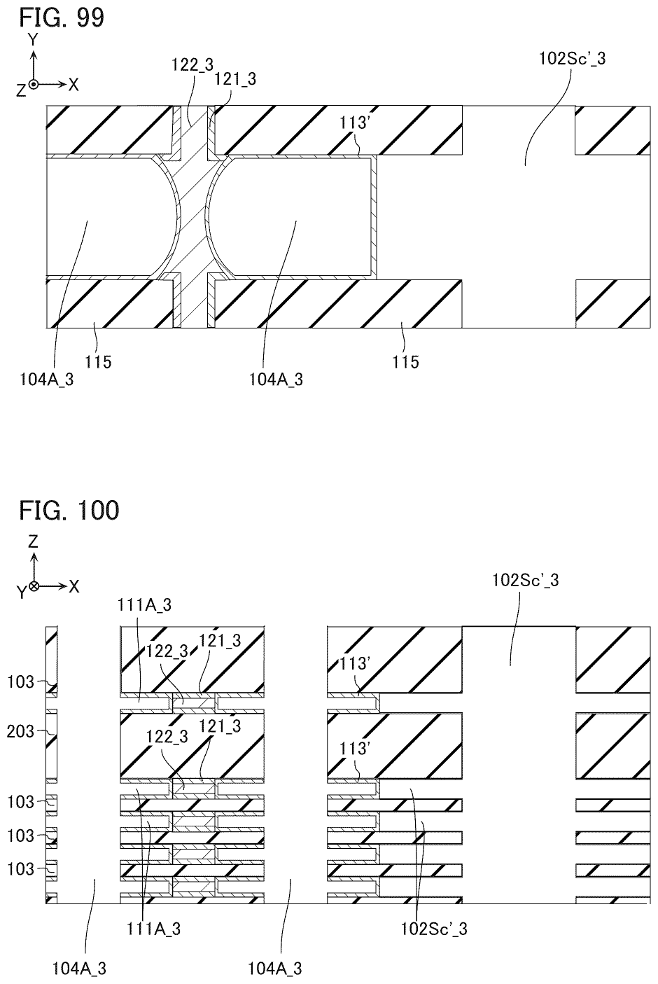

Next, as shown in FIGS. 99 and 100, for example, the conductive layer 113′ is formed inside the opening 111A_3. In this step, for example, a conductive film of the likes of titanium nitride (TiN) is formed inside the openings 104A_3, 111A_3. Next, on the inside of the opening 104A_3, parts (portions formed on side surfaces of the insulating layers 103, 203) of the conductive film are removed, and the conductive film divided in the Z-direction, whereby the conductive layer 113′ is formed. This step is performed by the likes of CVD and RIE, for example.

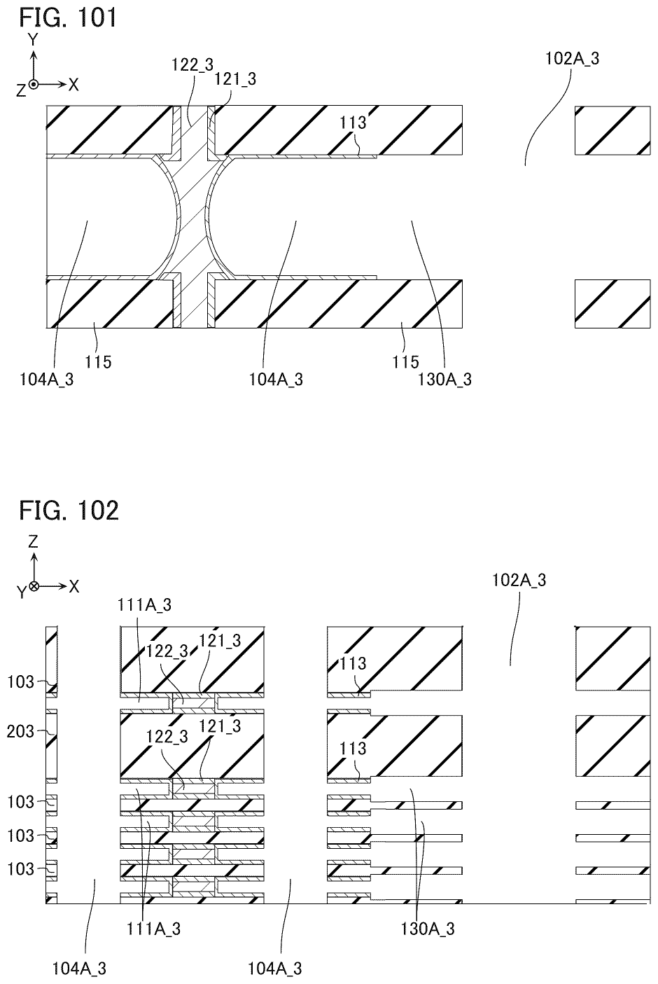

Next, as shown in FIGS. 101 and 102, for example, the sacrifice layer 102Sc′_3 is removed, and the openings 102A_3, 130A_3 formed. Moreover, parts of the upper surfaces and parts of the lower surfaces of the insulating layers 103, 203, and a part of the side surface in the X-direction of the conductive layer 113′ that have been exposed in the opening 130A_3, are removed, and the conductive layer 113 formed. This step causes width in the Z-direction of the opening 130A_3 to increase. This step is performed by the likes of wet etching, for example.

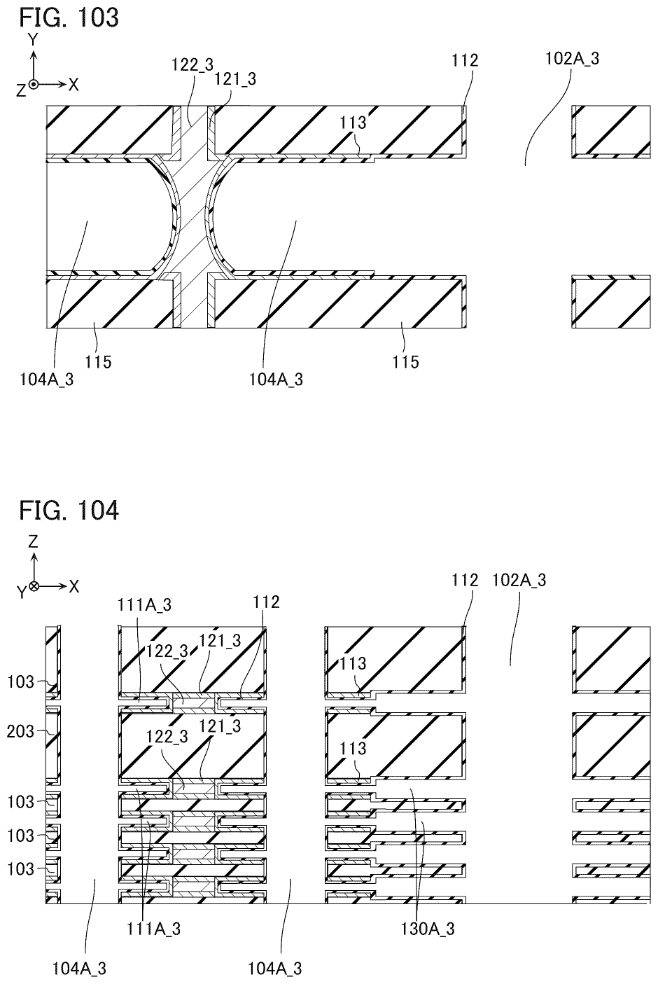

Next, as shown in FIGS. 103 and 104, for example, the insulating layer 112 is formed inside the openings 102A_3, 104A_3, 111A_3, 130A_3. This step is performed by the likes of CVD, for example.

Next, similarly to in the steps shown in FIGS. 30 to 49, the capacitor structure 130 or the electrode structure 130c is formed inside the opening 130A_3, the conductive layer 102(PL), and so on, are formed inside the opening 102A_3, the transistor structure 110 is formed inside the opening 111A_3, the via wiring 104, and so on, are formed inside the opening 104A_3, and the contact GBLC1 connected to the electrode structure 130c, and so on, are formed.

Next, for example, steps similar to the steps described with reference to FIGS. 50 to 58 are performed, and the structures described with reference to FIGS. 82 to 84 thereby formed.

### Advantages

The semiconductor memory device according to the present embodiment (FIG. 82), in comparison with the semiconductor memory device according to the first embodiment (FIG. 5), does not require the insulating layer 101. This makes it possible for density level of the semiconductor memory device to be raised. Moreover, by configuring steps with no formation of the insulating layer 101, a reduction in number of steps is enabled, and a contribution can be made to reducing manufacturing costs of the semiconductor memory device.

### Other Embodiments

That concludes description of the semiconductor memory devices according to the first through third embodiments. However, the semiconductor memory devices according to these embodiments are merely exemplifications, and their specific configurations, and so on, may be appropriately adjusted.

For example, in the semiconductor memory devices according to the second and third embodiments, there are shown examples where the via wiring 104(BL) comprises the inner region CAV. However, in the second and third embodiments, the via wiring 104(BL) may comprise a conductive member instead of the inner region CAV. The conductive member may include the likes of indium tin oxide (ITO), indium zinc oxide (IZO), ruthenium oxide (RuO₂), or iridium oxide (IrO₂), for example.

For example, in the semiconductor memory device according to the second embodiment, two transistor layers TL arranged in the Z-direction are exemplified. However, three or more transistor layers TL may be provided arranged in the Z-direction. The three or more transistors TrB provided in these three or more transistor layers TL may be connected in parallel between the via wiring 104(BL) and the global bit line GBL.

Moreover, in the above description, there is described an example where the capacitor CpC is adopted as the memory portion connected to the transistor structure 110. However, the memory portion need not be the capacitor CpC. For example, the memory portion may be one that includes a ferroelectric material, ferromagnetic material, chalcogen material of the likes of GeSbTe, or another material, and that utilizes characteristics of these materials to store data. For example, any of these materials may be included in an insulating layer between the electrodes forming the capacitor CpC, in any of the structures described above.

Moreover, the methods of manufacturing the semiconductor memory devices according to the first through third embodiments, too, may be appropriately adjusted. For example, an order of any two of the above-mentioned steps may be switched, or any two of the above-mentioned steps may be simultaneously executed.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory layers arranged in a first direction;
a via wiring extending in the first direction;
a first wiring which is provided on one side in the first direction with respect to the plurality of memory layers, and extends in a second direction intersecting the first direction; and
an insulating layer which is provided on the other side in the first direction with respect to the plurality of memory layers, and covers an end portion of the via wiring, wherein
the plurality of memory layers each comprise:
a semiconductor layer electrically connected to the via wiring;
a gate electrode facing the semiconductor layer;
a second wiring which extends in a third direction intersecting the first direction and the second direction, and is electrically connected to the gate electrode; and
a memory portion which is provided on an opposite side to the second wiring in the second direction with respect to the semiconductor layer, and is electrically connected to the semiconductor layer,
the via wiring comprises: a conductive member extending in the first direction; and an inner region extending in the first direction and having its outer peripheral surface surrounded by the conductive member, and
an end portion on an insulating layer side in the first direction of the inner region is not covered by the conductive member, and is covered by the insulating layer, or is continuous with the insulating layer.

2. The semiconductor memory device according to claim 1, wherein
the inner region contacts the insulating layer.

3. The semiconductor memory device according to claim 1, wherein
the inner region includes a cavity.

4. The semiconductor memory device according to claim 1, wherein
the inner region includes silicon oxide or silicon nitride.

5. The semiconductor memory device according to claim 1, wherein
the conductive member includes: a first oxide conductive layer extending in the first direction; and a second oxide conductive layer extending in the first direction, and
the second oxide conductive layer is provided between the first oxide conductive layer and the inner region.

6. The semiconductor memory device according to claim 1, wherein
the plurality of memory layers include:
a first memory layer provided at a position closest to the first wiring, in the first direction; and
a second memory layer provided at a position furthest from the first wiring, in the first direction, and
the inner region extends in the first direction from the first memory layer to the second memory layer.

7. The semiconductor memory device according to claim 1, comprising:
a plate wiring which extends in the first direction and is commonly electrically connected to a plurality of the memory portions; and
a conductive layer which is provided on an insulating layer side in the first direction with respect to the plurality of memory layers, and is provided at a position overlapping the via wiring viewed in the first direction, wherein
the plate wiring and the conductive layer are electrically connected.

8. The semiconductor memory device according to claim 1, comprising
a first chip and a second chip that are connected to each other, wherein
the first chip comprises:
the plurality of memory layers;
the via wiring;
the first wiring; and
a plurality of first bonding electrodes at least one of which is electrically connected to the first wiring,
the second chip comprises:
a substrate;
a plurality of transistors provided on a surface of the substrate; and
a plurality of second bonding electrodes electrically connected to the plurality of transistors, and
the plurality of first bonding electrodes are connected to the plurality of second bonding electrodes.

9. The semiconductor memory device according to claim 1, wherein
the gate electrode faces surfaces on one side and the other side in the first direction, and surfaces on one side and the other side in the third direction, of the semiconductor layer.

10. The semiconductor memory device according to claim 1, wherein
the semiconductor layer includes: at least one element of gallium (Ga) and aluminum (Al); indium (In); zinc (Zn); and oxygen (O).

11. A semiconductor memory device comprising:
a plurality of memory layers arranged in a first direction;
a first wiring which is provided on one side in the first direction with respect to the plurality of memory layers, and extends in a second direction intersecting the first direction;
a plurality of select transistor layers which are provided between the plurality of memory layers and the first wiring, and are arranged in the first direction;
a via wiring which extends in the first direction in a range in the first direction corresponding to the plurality of memory layers and the plurality of select transistor layers; and
a contact electrode which extends in the first direction in a range in the first direction corresponding to the plurality of select transistor layers, wherein the plurality of memory layers each comprise:
a first semiconductor layer electrically connected to the via wiring;
a first gate electrode facing the first semiconductor layer;
a second wiring which extends in a third direction intersecting the first direction and the second direction, and is electrically connected to the first gate electrode; and
a memory portion which is provided on an opposite side to the second wiring in the second direction with respect to the first semiconductor layer, and is electrically connected to the first semiconductor layer,
the plurality of select transistor layers each comprise:
a second semiconductor layer electrically connected to the via wiring;
a second gate electrode facing the second semiconductor layer;
a third wiring which extends in the third direction and is electrically connected to the second gate electrode; and
a connecting electrode which is provided on an opposite side to the third wiring in the second direction with respect to the second semiconductor layer, and is electrically connected to the second semiconductor layer and the first wiring,
the contact electrode is continuous with a plurality of the connecting electrodes included in the plurality of select transistor layers, and
the contact electrode and the plurality of connecting electrodes include an integrally formed oxide conductive layer.

12. The semiconductor memory device according to claim 11, wherein
a part of the oxide conductive layer included in the contact electrode contacts the first wiring, and
a part of the oxide conductive layer included in the connecting electrode contacts the second semiconductor layer.

13. The semiconductor memory device according to claim 11, wherein
the via wiring comprises a first surface on a side close to the first wiring in the first direction,
the contact electrode comprises a second surface on a side close to the first wiring in the first direction, and
a position in the first direction of the second surface is closer to the first wiring than is a position in the first direction of the first surface.

14. The semiconductor memory device according to claim 11, wherein
the via wiring comprises a first surface on a side close to the first wiring in the first direction,
the contact electrode comprises a second surface on a side close to the first wiring in the first direction, and
a position in the first direction of the second surface is further from the first wiring than is a position in the first direction of the first surface.

15. The semiconductor memory device according to claim 11, wherein
the first semiconductor layer and the second semiconductor layer include: at least one element of gallium (Ga) and aluminum (Al); indium (In); zinc (Zn); and oxygen (O).

16. A semiconductor memory device comprising:
a plurality of memory layers arranged in a first direction;
a first via wiring extending in the first direction; and
a second via wiring whose position in a second direction intersecting the first direction differs from that of the first via wiring, and that extends in the first direction, wherein
the plurality of memory layers each comprise:
a wiring which is provided between the first via wiring and the second via wiring, and extends in a third direction intersecting the first direction and the second direction;
a first semiconductor layer electrically connected to the first via wiring;
a first gate electrode which faces the first semiconductor layer and is electrically connected to the wiring;
a first memory portion which is provided on an opposite side to the wiring in the second direction with respect to the first semiconductor layer, and is electrically connected to the first semiconductor layer;
a second semiconductor layer electrically connected to the second via wiring;
a second gate electrode which faces the second semiconductor layer and is electrically connected to the wiring; and
a second memory portion which is provided on an opposite side to the wiring in the second direction with respect to the second semiconductor layer, and is electrically connected to the second semiconductor layer, and
the wiring is not provided with a through-hole extending in the first direction.

17. The semiconductor memory device according to claim 16, wherein
the first semiconductor layer and the second semiconductor layer include: at least one element of gallium (Ga) and aluminum (Al); indium (In); zinc (Zn); and oxygen (O).
